(19) United States
(12) Patent Application Publication
(10) Pub. No.: US 2025/0298759 A1
(43) Pub. Date: Sep. 25, 2025

(54) METHODS AND APPARATUS TO ACCESS MAIN MEMORY

(71) Applicant: Openchip & Software Technologies S.L., Barcelona (ES)

(72) Inventors: Francesc Guim Bernat, Barcelona (ES); Violante Moschiano, Avezzano (IT); Luigi Pilolli, L’Aquila (IT); Guido Luciano Rizzo, Albignasego (IT); Erich Ludwig Focht, Stuttgart (DE)

(21) Appl. No.: 19/186,321

(22) Filed: Apr. 22, 2025

Related U.S. Application Data
(63) Continuation of application No. PCT/EP2025/057100, filed on Mar. 14, 2025.

(30) Foreign Application Priority Data
Mar. 14, 2025 (WO) PCT/EP2025/057100

(51) Int. Cl. G06F 13/16; G06F 13/40

(52) U.S. Cl. CPC G06F 13/1673; G06F 13/1642; G06F 13/1689; G06F 13/4022

(57) ABSTRACT

Systems, apparatus, articles of manufacture, and methods are disclosed. An example apparatus includes main memory, a memory hierarchy in circuit with the memory, buffer circuitry in circuit with the memory, and control circuitry to selectively couple programmable circuitry to the main memory via the cache circuitry or to the main memory via the buffer circuitry.

### FIELD OF THE DISCLOSURE

This disclosure relates generally to computer architecture and, more particularly, to methods and apparatus to access main memory.

### BACKGROUND

Workloads sent to programmable circuitry for execution can be categorized as compute-intense or memory-intense. In compute-intense workloads, the number and type of operations generally places a larger burden on system resources than the amount of data that the operations are performed on. Conversely, in memory-intense workloads, the amount of data being operated on generally places a larger burden on system resources than the number or type of operations that use the data.

### BRIEF DESCRIPTION OF THE DRAWINGS

FIG. 1 is a block diagram of an example environment in which example programmable circuitry performs operations.

FIG. 2A is a block diagram of an example implementation of the memory hierarchy and the input switch circuitry of FIG. 1.

FIG. 2B is a block diagram of an example implementation of the memory hierarchy and the output switch circuitry of FIG. 1.

FIG. 3 is an illustrative example of the performance of a device implemented as described in FIG. 1.

FIG. 4 is a first flowchart representative of example machine readable instructions and/or example operations that may be executed, instantiated, and/or performed by example programmable circuitry to implement a read workload.

FIG. 5 is a second flowchart representative of example machine readable instructions and/or example operations that may be executed, instantiated, and/or performed by example programmable circuitry to implement a read workload.

FIG. 6 is a flowchart representative of example machine readable instructions and/or example operations that may be executed, instantiated, and/or performed by example programmable circuitry to implement a write workload.

FIG. 7 illustrates an example hardware arrangement of an example data center.

FIG. 8A illustrates an example arrangement of an example chip assembly of FIG. 7

FIG. 8B illustrates an example arrangement of an example chip assembly of FIG. 7, adapted for high-performance computing applications.

FIG. 9 is a block diagram of an example processing platform including programmable circuitry structured to execute, instantiate, and/or perform the example machine readable instructions and/or perform the example operations of FIGS. 4-6 to implement the compute device of FIG. 1.

FIG. 10 is a block diagram of an example implementation of the programmable circuitry of FIG. 9.

FIG. 11 is a block diagram of another example implementation of the programmable circuitry of FIG. 9.

FIG. 12 is a block diagram of an example software/firmware/instructions distribution platform (e.g., one or more servers) to distribute software, instructions, and/or firmware (e.g., corresponding to the example machine readable instructions of FIGS. 4-6) to client devices associated with end users and/or consumers (e.g., for license, sale, and/or use), retailers (e.g., for sale, re-sale, license, and/or sub-license), and/or original equipment manufacturers (OEM s) (e.g., for inclusion in products to be distributed to, for example, retailers and/or to other end users such as direct buy customers).

In general, the same reference numbers will be used throughout the drawing(s) and accompanying written description to refer to the same or like parts. The figures are not necessarily to scale.

### DETAILED DESCRIPTION

Compute-intense workloads generally include more data and/or instruction reusage than memory-intense workloads. For example, programmable circuitry that loads data and/or instructions from main memory for use in a compute-intense workload is likely to perform a comparatively large number of operations on the data (e.g., the programmable circuitry re-uses the data across multiple operations) before writing the data back to main memory. In contrast, memory-intense workloads perform a comparatively small number of operations before writing said data back to main memory. As used above and herein, the term “instruction” refers to one or more operators that cause programmable circuitry to perform one or more operations. The term “data” refers to the operands (e.g., the values) on which the operations are performed.

Known compute devices implement various types of memory hierarchies to support data and/or instruction reusage in compute-intense workloads. As used above and herein, a memory hierarchy refers to a system in which memory resources are organized into two or more levels between the main memory and the programmable circuitry. In some examples, a level within a memory hierarchy may be referred to as a cache (e.g., a micro cache, a Level 1 (L1) cache, a Level 3 (L2) cache, etc).

Data and instructions move through memory hierarchies using adjacent levels. For example, suppose a memory hierarchy has xlevels, where the first level accesses data and/or instructions directly from main memory and the programmable circuitry accesses data and/or instructions directly from the xth level. In such examples, if programmable circuitry that requires data that is currently stored in the main memory, the data and/or instructions is first transferred from the main memory to the first level of the hierarchy, then is transferred from the first level to the second level, . . . , then is transferred from the (x-1)th level to the xth level, and then is read by the programmable circuitry from the xth level. Memory hierarchies support data and/or instruction reusage (and therefore supports compute-intense workloads) by storing frequently used data and/or instructions in memory levels near the programmable circuitry. This practice reduces the number of transfers between levels required for the programmable circuitry to access the frequently used data and/or instructions, which in turn reduces the amount of time and the amount of power required for the frequently used data and/or instructions. In some examples, the foregoing practice also reduces the physical distance between a) the frequently used data and/or instructions and b) the programmable circuitry. As used herein, the practice of storing frequently used data and/or instructions in memory levels near the programmable circuitry is referred to as data and/or instruction locality. Typically, cache/memory levels closer to the programmable circuitry are faster and smaller than cache/memory levels farther from the programmable circuitry.

While the structure of memory hierarchies provides a performance advantage to compute-intense workloads as described above, the same structure also limits the performance of memory-intense workloads. Data and/or instruction reusage is less prevalent in memory-intense workloads than it is in compute-intense workloads as described above. Accordingly, memory-intense workloads have less data and/or instructions that can be referred to as “frequently used” and therefore do not benefit from storage at a level near the programmable circuitry (e.g., since the cache closest to the programmable circuitry is small, there are frequent cache misses and, thus, a frequent need to reach all the way out to main memory). In other words, many operations in memory-intense workloads require data and/or instructions that are different from the previously executed operation. Accordingly, programmable circuitry that uses a memory hierarchy when implementing a memory-intense workload must wait for most of the data and/or instructions to travel through each of the xlevels of the hierarchy before the data and/or instructions can be accessed. This frequent traversal of data and/or instructions through the entire memory hierarchy adds time, consumes power, and generally decreases the performance of memory-intense workloads.

Historically, most applications were developed with compute-intense workloads because the performance capabilities of programmable circuitry were relatively weak. For example, applications that are developed for execution on a general purpose processor (e.g., a Central Processor Unit) are generally considered compute-intense workloads. Examples of compute-intense workloads include but are not limited to Internet browsing, word processing, spread sheet applications, etc. However, as the performance capabilities of programmable circuitry improves, industries have developed more applications with memory-intense workloads. Such applications include but are not limited to training or executing machine learning models, graphics rendering for media or video games, etc. The performance of such applications is limited in known compute devices due to the frequent transfer of data and/or instructions across the entire memory hierarchy as described above.

Some applications also rely on High Performance Computing (HPC), which refers to the practice of aggregating computing resources (e.g., multiple machines, multiple compute nodes within a machine, etc.) to gain performance greater than that of a single workstation, server, or computer. HPC applications are generally memory-intense workloads with very little data and/or instruction reusage. Therefore, the performance of HPC applications are limited by memory hierarchies as described above. M ore generally, known compute devices that rely on memory hierarchies no longer support the efficient data and/or instruction transfer of all possible use cases due to the rising prevalence of memory-intense workloads.

Example methods, apparatus, and systems described herein implement a compute device that efficiently transfers data and/or instructions for both compute-intense workloads and memory-intense workloads. An example compute device includes two paths between main memory and programmable circuitry. The first path includes a memory hierarchy (e.g., a cache hierarchy) in circuit with the main memory. When executing a compute-intense workload, the programmable circuitry can access data using the memory hierarchy to leverage data and/or instruction locality as described above. In the second example path, the memory hierarchy is replaced by a buffer circuitry in circuit with the main memory, such as a First In First Out (FIFO) buffer. When executing a memory-intense workload, an instance of the programmable circuitry can access data and/or instructions from main memory using only one intermediate transfer (the FIFO buffer) to account for differences in read and write speeds. The example compute device includes switch circuitry that selectively couples the programmable circuitry to either the FIFO buffer or the memory hierarchy. The example compute device also includes control circuitry that sets the state of the switch circuitry based on whether a given workload is characterized as compute-intense or memory-intense, thereby causing delivery of data to the programmable circuitry via either the FIFO buffer or the memory hierarchy. The control circuitry determines this characterization by performing prediction operations before run time and/or performing measurement operations during run time. In some examples, the terms FIFO buffer, FIFO queue, and buffer circuitry may be used interchangeably.

The following introduces examples of computer hardware for data and/or instruction transfer operations, applicable in programmable architectures such as chiplet-based processors, System-on-chip (SoC) circuitry, System-in-Package (SiP) or System-on-Package (SoP) circuitry, and/or any other modular packaging implementations of programmable circuitry.

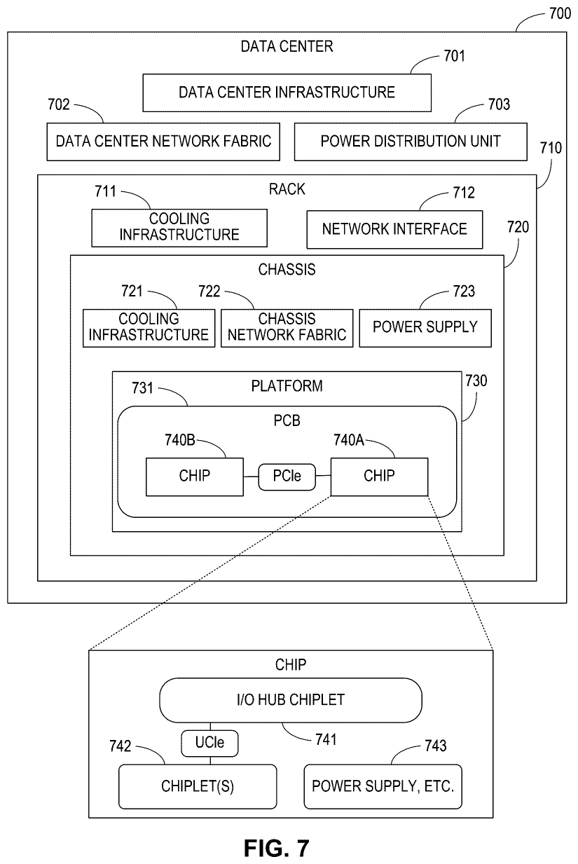

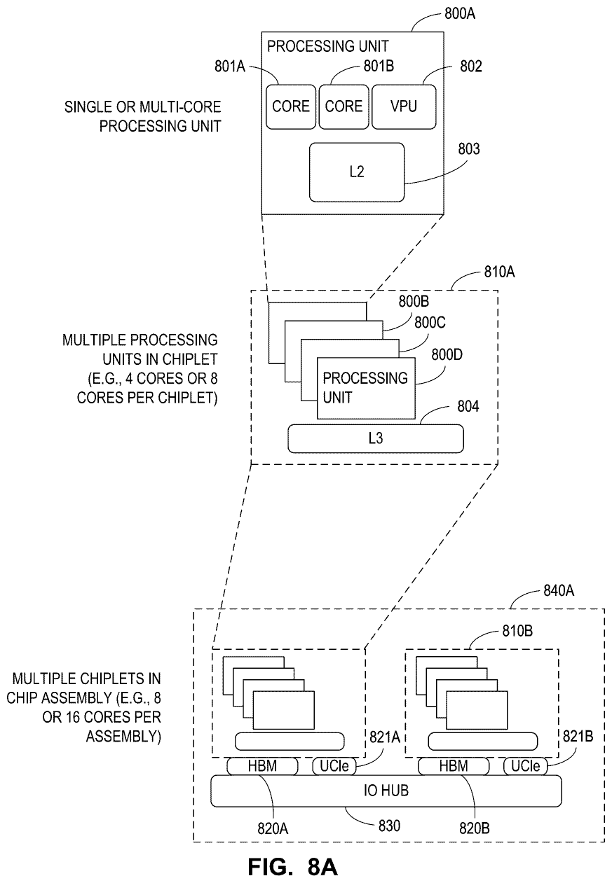

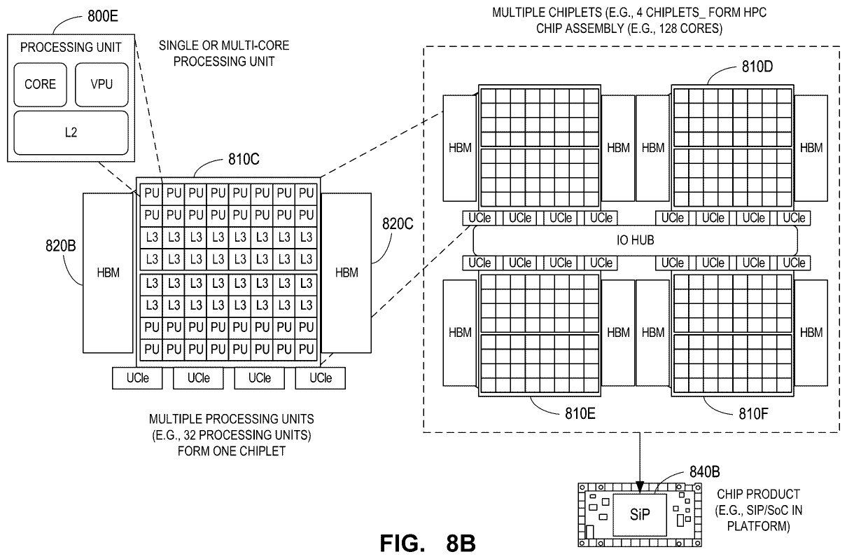

As used herein, a chiplet refers to any integrated circuit (IC) that has a modular structure designed to have one or more functionalities and to be combinable with one or more other chiplets on an interposer or other substrate in a package. Examples of chiplets are compute chiplets that include programmable circuitry (e.g., one or more processor circuits, such as one or more cores, etc.) and supporting circuitry (e.g., local memory, etc.) to provide computational functionality (e.g., to execute a host OS, applications, etc.), memory chiplets that include memory accessible to one or more other chiplets, communication chiplets that include communication interfaces (e.g., input/output hubs, networks, etc.) to enable other chiplets to communicate with each other and/or to other devices external to the package, etc. Example multi-tier management architectures provide a flexible management architecture that is multi-tiered to enable management of chiplet-based compute devices that include various combinations of chiplets from various manufacturers. Example implementation of chiplets are further described below in conjunction with FIGS. 7, 8A, and 8B.

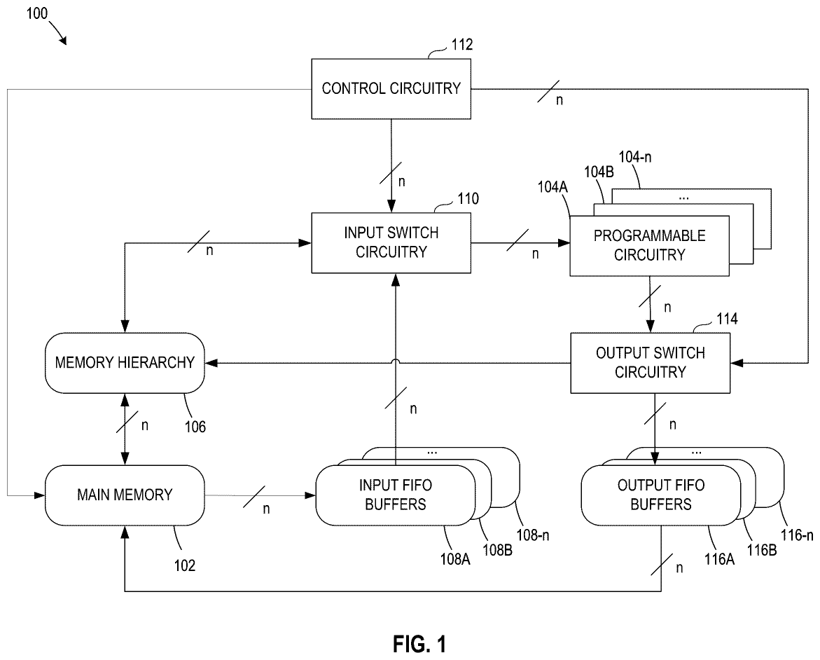

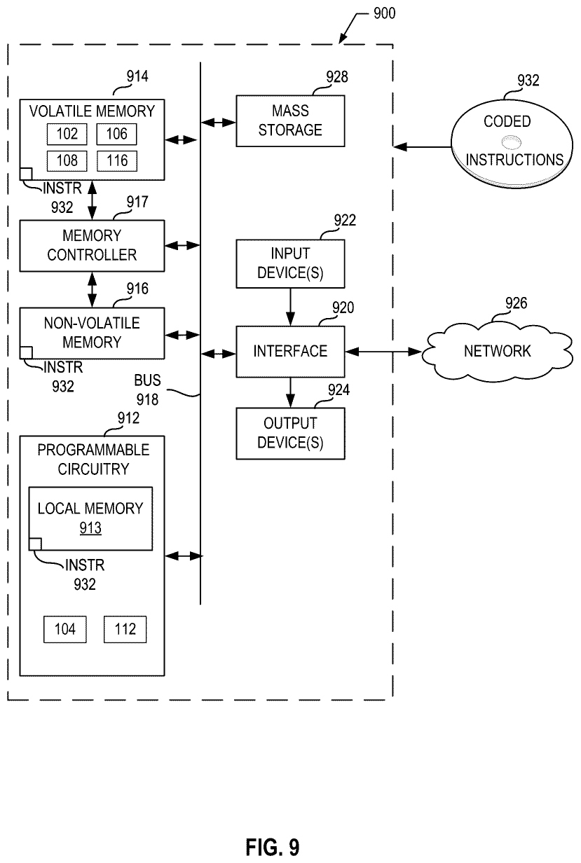

FIG. 1 is a block diagram of an example compute device 100. In some examples, the compute device 100 is referred to as a programmable circuitry platform as described further in connection with FIG. 9. The compute device 100 includes example main memory 102, example programmable circuitry 104A, 104B, . . . , 104-n (collectively referred to as programmable circuitry 104), an example memory hierarchy 106, example input FIFO buffers 108A, 108B, . . . , 108-n (collectively referred to as input FIFO buffers 108), example input switch circuitry 110, example control circuitry 112, example output switch circuitry 114, example output FIFO buffers 116A, 116B, . . . , 116-n (collectively referred to as output FIFO buffers 116).

The compute device 100 refers to any electronic device that is tasked with executing both compute-intense workloads and memory-intense workloads. In addition to its categorization as either compute-intense or memory-intense as described above, a given workload described in examples herein can be further categorized as either a read-workload or a write-workload. As used herein, a read-workload refers to a set of read operations in which the programmable circuitry 104 obtains data and/or instructions from a memory resource. This memory resource may include, but is not limited to, the main memory 102. Similarly, as used herein, a write-workload refers to a set of write operations in which the programmable circuitry 104 stores data and/or instructions in a memory resource. A given application or use case may therefore correspond to any number of read-workloads and write-workloads that are organized in any order. Similarly, a read-workload may refer to any number of read operations and a write-workload may correspond to any number of write operations.

In this example, the main memory 102 stores data and/or instructions to be used by the programmable circuitry 104 to implement (e.g., execute, perform, instantiate, etc.) workloads. The main memory 102 is generally larger, but transfers data and/or instructions slower, than the various other levels of the memory (e.g., cache) hierarchy 106, the input FIFO buffers 108, and the output FIFO buffers 116. In this example, the main memory 102 is implemented by Dynamic Random Access Memory (DRAM). In other examples, the main memory 102 may be additionally or alternatively implemented by a different type of memory. In some examples, the main memory 102 includes or is in circuit with memory controller circuitry that manages the transfer of data into and out of the main memory 102.

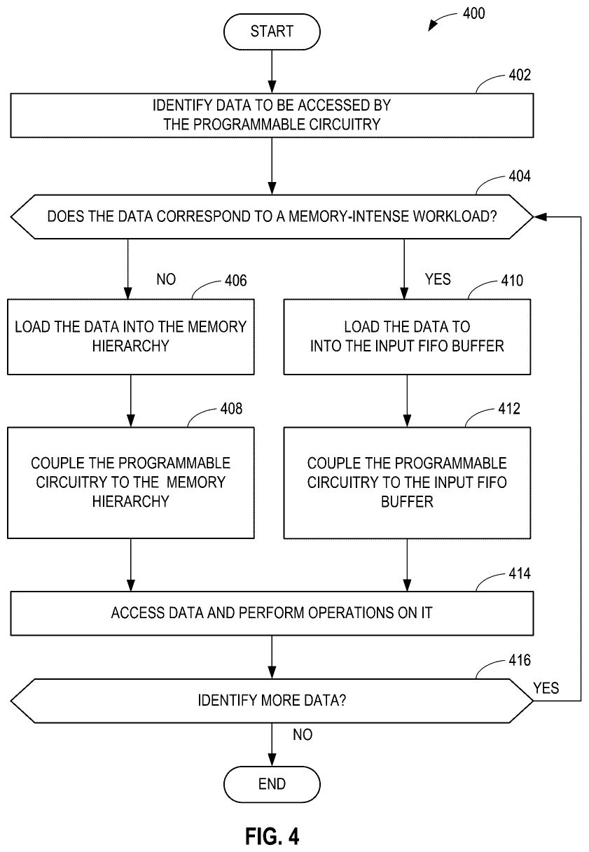

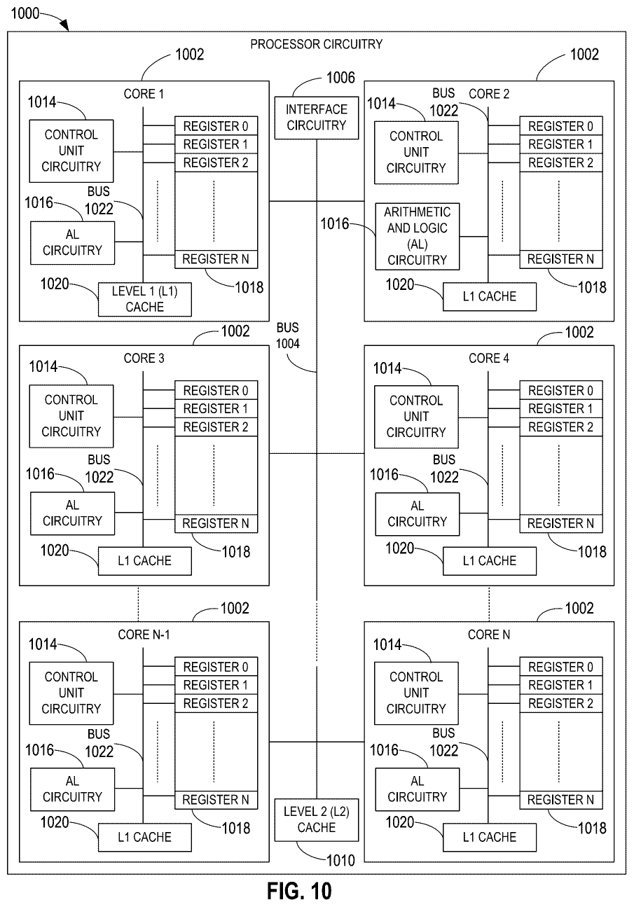

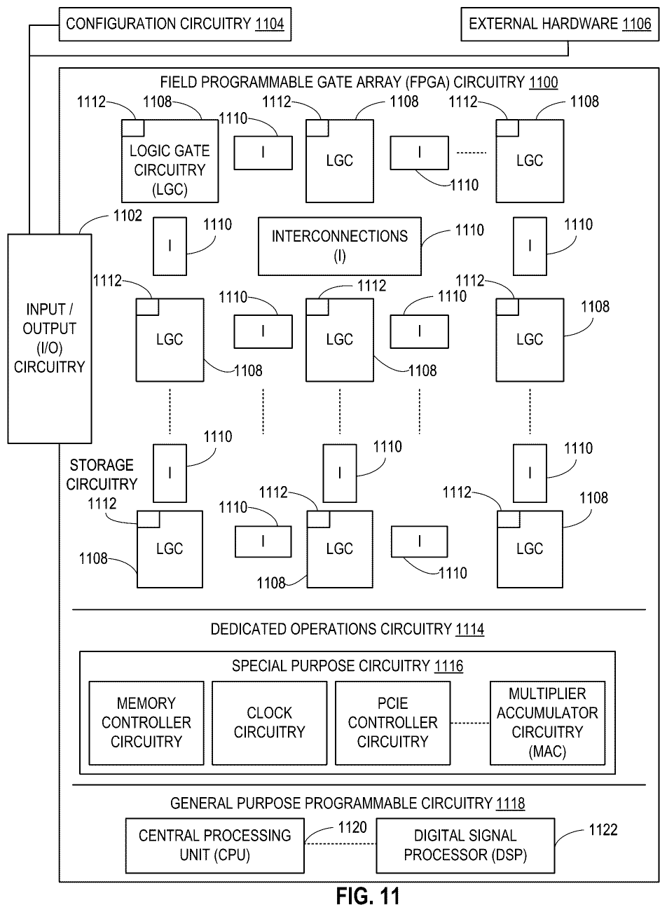

In some examples, the compute device 100 includes means for storing data and/or instructions. For example, the means for storing data and/or instructions may be implemented by the main memory 102. In some examples, memory controller circuitry associated with the main memory 102 may be instantiated by programmable circuitry such as the example programmable circuitry 912 of FIG. 9. For instance, the memory controller circuitry associated with the main memory 102 may be instantiated by the example microprocessor 1000 of FIG. 10 and/or the chiplet of FIGS. 8A and/or 8B executing machine executable instructions such as those implemented by at least blocks 406, 410, 504, 614 of FIGS. 4-6. In some examples, the memory controller circuitry associated with the main memory 102 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the memory controller circuitry associated with the main memory 102 may be instantiated by any other combination of hardware, software, and/or firmware. For example, the memory controller circuitry associated with the main memory 102 may be implemented by at least one or more hardware circuits (e.g., processor circuitry, discrete and/or integrated analog and/or digital circuitry, an FPGA, an ASIC, an XPU, chiplet(s), core(s), a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

In this example, the programmable circuitry 104 implements read-workloads by obtaining data and/or instructions from the main memory 102. The programmable circuitry 104 also implements write-workloads in this example by storing data and/or instructions in the main memory 102. In other example, the programmable circuitry 104 implements read-workloads and/or write-workloads from a different memory resource. The programmable circuitry 104 may be implemented using any type of programmable circuitry, including but not limited to programmable microprocessors, Field Programmable Gate Arrays (FPGA s) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). FIG. 1 shows the compute device 100 is implemented with n instances of programmable circuitry, where n is any positive integer. In some examples, a given instance of programmable circuitry 104A is implemented by a core of a processor.

In general, an integrated circuit (IC) that implements a given instance of the programmable circuitry 104 includes both a) a pipeline of Arithmetic Logic Units (ALUs) and Floating Point Operating Units (FPU) that perform multiple operations in parallel, and b) a small local memory (e.g., micro cache) used to temporarily store data and/or instructions before and/or after the performance of operations by the pipeline. In examples described herein, the local memory implemented within the programmable circuitry 104 are referred to as registers. In some contexts, a register may be additionally or alternatively referred to as a level 1 cache or micro cache. However, in some examples disclosed herein, the registers within the programmable circuitry 104 are separate and independent from the cache levels of the memory hierarchy 106. Thus, as described further below, registers within a given instance of the programmable circuitry 104A may be used in either a) a first path for read operations that includes the memory hierarchy 106 or b) a second path for read operations that includes the input FIFO buffers 108 but does not include the memory hierarchy 106. The registers within a given instance of the programmable circuitry 104A may also be used in either a) a first path for write operations that includes the memory hierarchy 106 or b) a second path for write operations that includes the output FIFO buffers 116 but does not include the memory hierarchy 106.

In some examples, the compute device 100 includes means for implementing a workload. For example, the implementing means may be implemented by the programmable circuitry 104. In some examples, the programmable circuitry 104 may be instantiated by the example programmable circuitry 912 of FIG. 9. For instance, the programmable circuitry 104 may be instantiated by the example microprocessor 1000 of FIG. 10 and/or the chiplet of FIGS. 8A and/or 8B executing machine executable instructions such as those implemented by at least blocks 414, 506, 614 of FIGS. 4-6. In some examples, the programmable circuitry 104 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the programmable circuitry 104 may be instantiated by any other combination of hardware, software, and/or firmware. For example, the programmable circuitry 104 may be implemented by at least one or more hardware circuits (e.g., processor circuitry, discrete and/or integrated analog and/or digital circuitry, an FPGA, an ASIC, an XPU, chiplet(s), core(s), a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

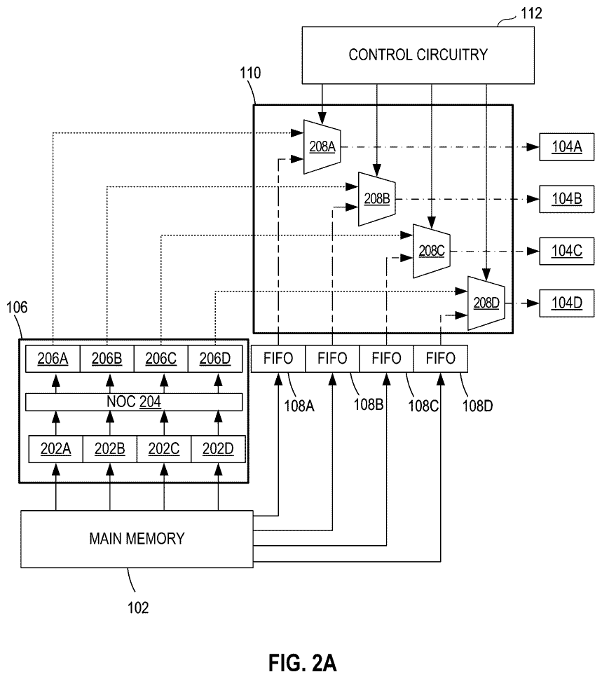

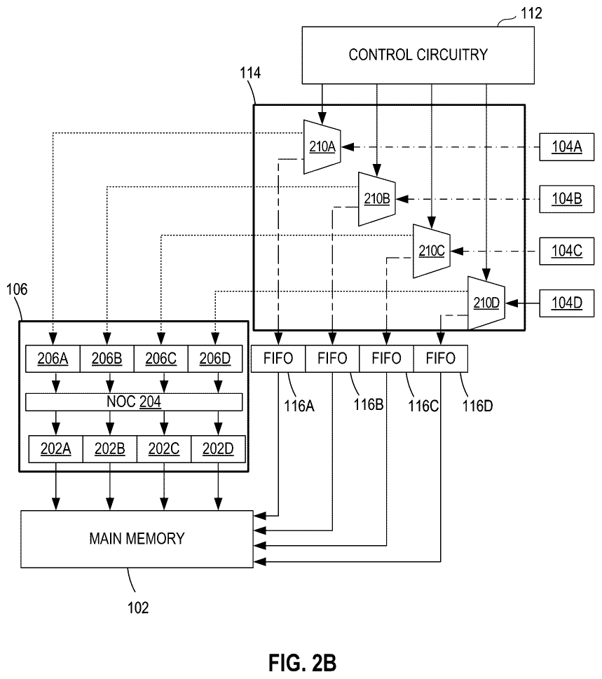

The memory hierarchy 106 of this example is a multi-level cache structure that transfers data and/or instructions between the main memory 102 and programmable circuitry 104. In some examples, the memory hierarchy 106 includes or is in circuit with memory controller circuitry that manages the transfer of data between the cache levels and measures the performance of one or more cache levels. The memory hierarchy 106 supports data and/or instruction locality as described above. The memory hierarchy 106 has n terminals in circuit with the main memory 102 to both read and write data and/or instructions to and from the main memory 102. The memory hierarchy 106 also has n terminals in circuit with the input switch circuitry 110 and n terminals in circuit with the output switch circuitry 114. In some examples, the memory hierarchy 106 is referred to as cache circuitry. The memory hierarchy 106 is described further in connection with FIGS. 2A and 2B.

In some examples, the compute device 100 includes first means for data and/or instruction transfer. For example, the first means for data and/or instruction transfer may be implemented by memory hierarchy 106. In some examples, memory controller circuitry associated with the memory hierarchy 106 may be implemented by the example programmable circuitry 912 of FIG. 9. For instance, the memory controller circuitry associated with the memory hierarchy 106 may be instantiated by the example microprocessor 1000 of FIG. 10 and/or the chiplet of FIGS. 8A and/or 8B executing machine executable instructions such as those implemented by at least blocks 406, 506, 608, 612 of FIGS. 4-6. In some examples, memory controller circuitry associated with the memory hierarchy 106 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the memory controller circuitry associated with the memory hierarchy 106 may be instantiated by any other combination of hardware, software, and/or firmware. For example, memory controller circuitry associated with the memory hierarchy 106 may be implemented by at least one or more hardware circuits (e.g., processor circuitry, discrete and/or integrated analog and/or digital circuitry, an FPGA, an ASIC, an XPU, chiplet(s), core(s), a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The input FIFO buffers 108 transfer data and/or instructions from the main memory 102 to the programmable circuitry 104. Accordingly, the compute device 100 implements one input FIFO buffer 108A per instance of programmable circuitry 104A. A given input FIFO buffer 108A may be implemented by a one-dimensional memory unit that temporarily stores data and/or instructions from the main memory 102. In this example, the programmable circuitry 104A reads data and/or instructions from the input FIFO buffer 108A in chronological order such that if two values are written into the buffer at T0 and T1 respectively, the value from T0 is read from the buffer before the value from T1. In other examples, the programmable circuitry 104A reads data and/or instructions from the input buffers 108 using one more techniques different than First In First Out. The input FIFO buffers 108 are generally smaller (e.g., has less memory capacity), but transfer data faster, than the memory hierarchy 106.

In some examples, the compute device 100 includes second means for data and/or instruction transfer. For example, the second means for data and/or instruction transfer may be implemented by the input FIFO buffers 108.

The input switch circuitry 110 has a first set of n input terminals in circuit with the memory hierarchy 106, a second set of n input terminals in circuit with the respective input FIFO buffers 108, and a set of n output terminals in circuit with the programmable circuitry 104. The input switch circuitry 110 couples the input terminal of a given instance of the programmable circuitry (e.g., 104A) to either the memory hierarchy 106 or to the corresponding input FIFO buffer (e.g., 108A) based on instructions from the control circuitry 112. Thus, when the control circuitry 112 causes the input switch circuitry to change state, at least one instance of the programmable circuitry 104 decouples from one path to the main memory 102 and recouples to a second path to the main memory 102. The input switch circuitry 110 is described further in connection with FIG. 2A.

In some examples, the compute device 100 includes first means for switching. For example, the first means for switching may be implemented by the input switch circuitry 110.

In known compute devices, the memory hierarchy (e.g., the multi-level cache system) is the only path for data and/or instruction transfer between the main memory and the programmable circuitry. Known compute devices therefore regularly transfer data and/or instructions through the entire memory hierarchy when implementing memory-intense workloads, thereby limiting their performance as described above. In contrast, the example compute device 100 includes two paths for the programmable circuitry 104 to read from the main memory 102. The first path uses the memory hierarchy 106 while the second, alternate path that does not include the memory hierarchy 106. Accordingly, by changing the state of the input switch circuitry 110 to couple one of the first path or the second path to a given instance of the programmable circuitry 104A, the compute device 100 supports both efficient execution of compute-intense workloads via the first path and efficient execution of memory-intense workloads via the second path.

Memory-intense workloads have comparatively little data and/or instruction reusage compared to compute-intense workloads. Advantageously, the compute device 100 includes the input FIFO buffers 108 on the foregoing second path (e.g., the path without the memory hierarchy 106). The input FIFO buffers 108 reconcile the difference in read and write speeds, thereby making the making the second read-path compatible for communication between the main memory 102 and the programmable circuitry 104 while simultaneously reducing (e.g., minimizing) the number of intermediate memory structures.

The control circuitry 112 causes delivery of data by selectively coupling the programmable circuitry 104 to the memory hierarchy 106, the input FIFO buffers 108, and/or the output FIFO buffers 116. To do so, the control circuitry 112 first categorizes a given workload as either compute-intense or memory-intense. Techniques implemented by the control circuitry 112 for workload categorization are explained further below in the examples of FIGS. 4-6. If the control circuitry 112 determines a read-workload is compute-intense, the control circuitry 112 instructs the input switch circuitry 110 to couple the corresponding instance of the programmable circuitry 104A to the memory hierarchy 106. Therefore, performance is increased in this example by leveraging the data and/or instruction locality of the compute-intense read-workload. Alternatively, if the control circuitry 112 determines the read-workload is memory-intense, the control circuitry 112 instructs the input switch circuitry 110 to couple the corresponding instance of the programmable circuitry 104A to the corresponding input FIFO buffer 108A. Therefore, performance is increased in this example by performing data and/or instruction transfers that avoid the memory hierarchy 106. The control circuitry 112 also provides instructions to the output switch circuitry 114 and provides instructions to the main memory 102 as described further below. In some examples, the control circuitry 112 provides instructions to memory controller circuitry that is associated with the main memory 102 in addition to, or in replacement of, providing instructions directly to the main memory 102. In some examples, the control circuitry 112 is instantiated by programmable circuitry executing control instructions and/or configured to perform operations such as those represented by the flowchart(s) of FIGS. 4-6.

The control circuitry 112 may be instantiated (e.g., creating an instance of, bring into being for any length of time, materialize, implement, etc.) by programmable circuitry. For example, programmable circuitry may be implemented by a Central Processor Unit (CPU) a chiplet, an array of chiplets, a programmable logic device (PLD), a generic array logic (GAL) device, a programmable array logic (PAL) device, a complex programmable logic device (CPLD), a simple programmable logic device (SPLD), a microcontroller (M CU), a programmable system on chip (PSoC), etc. Additionally or alternatively, the control circuitry 112 of FIG. 1 may be instantiated (e.g., creating an instance of, bring into being for any length of time, materialize, implement, etc.) by (i) an Application Specific Integrated Circuit (ASIC) and/or (ii) a Field Programmable Gate Array (FPGA) (e.g., another form of programmable circuitry) structured and/or configured in response to execution of second instructions to perform operations corresponding to the first instructions. It should be understood that some or all of the circuitry of FIGS. 1-2B may, thus, be instantiated at the same or different times. Some or all of the circuitry of FIGS. 1-2B may be instantiated, for example, in one or more threads executing concurrently on hardware and/or in series on hardware. Moreover, in some examples, some or all of the circuitry of FIGS. 1-2B may be implemented by microprocessor circuitry executing instructions and/or FPGA circuitry performing operations to implement one or more virtual machines and/or containers.

In some examples, the control circuitry 112 is implemented by an AI agent. An AI agent is hardware, software, and/or firmware that is capable of autonomously performing a task. For example, an AI agent is implemented by at least one AI/ML model such as an NN (e.g., a CNN, an RNN, an LSTM network, a DBN, an autoencoder network, an encoder-decoder network, a GAN, an RBFN, an MLP network, a large-language model (LLM), etc.). An AI agent can be implemented as a simple reflex agent, a model-based reflex agent, a goal-based agent, a utility-based agent, or a learning agent, among others. In some examples, an AI agent can be updated after deployment, (e.g., by an administrator of a compute deployment, by a provider of the AI agent, etc.).

A simple reflex agent refers to an AI agent that takes actions based on presently available information. As such, a simple reflex agent may not utilize memory or interact with other agents (if the simple reflex agent is missing information in an input). A model-based reflex agent refers to an AI agent that takes actions based on presently available information and memory to maintain a model of an environment in which the AI agent is deployed. As such, a model-based reflex agent can be updated as new information is received or learned.

A goal-based agent refers to an AI agent that includes a model of an environment in which the AI model is deployed. A goal-based agent takes actions based on the model and at least one goal. As such, a goal-based agent can search for a sequences of actions to achieve a goal. A utility-based agent refers to an AI agent that selects a sequence of actions to achieve at least one goal and to increase (e.g., maximize) utility, for example, measured by a reward function.

A learning agent refers to an AI agent that can learn from new information autonomously. A learning agent can be goal-based or utility-based in reasoning. A learning agent includes (1) a learner to learn from an environment in which the learning agent is deployed, (2) a critic to provide feedback on at least one action taken by the learning agent satisfied a threshold (e.g., reward, goal, etc.), (3) an actor to select an action to be performed by the learning agent, and (4) an action generator to propose at least one candidate action to be taken. As such, learning agents can achieve better performance than other AI agents in unfamiliar environments

In some examples, the compute device 100 includes means for controlling switch circuitry. For example, the means for controlling the switch circuitry may be implemented by control circuitry 112. In some examples, the control circuitry 112 may be instantiated by programmable circuitry such as the example programmable circuitry 912 of FIG. 9. For instance, the control circuitry 112 may be instantiated by the example microprocessor 1000 of FIG. 10 and/or the chiplet of FIGS. 8A and/or 8B executing machine executable instructions such as those implemented by at least blocks 402, 404, 416, 502, 508, 510, 518, 602, 604-612, 616 of FIGS. 4-6. In some examples, the control circuitry 112 may be instantiated by hardware logic circuitry, which may be implemented by an ASIC, XPU, or the FPGA circuitry 1100 of FIG. 11 configured and/or structured to perform operations corresponding to the machine readable instructions. Additionally or alternatively, the control circuitry 112 may be instantiated by any other combination of hardware, software, and/or firmware. For example, the control circuitry 112 may be implemented by at least one or more hardware circuits (e.g., processor circuitry, discrete and/or integrated analog and/or digital circuitry, an FPGA, an ASIC, an XPU, chiplet(s), core(s), a comparator, an operational-amplifier (op-amp), a logic circuit, etc.) configured and/or structured to execute some or all of the machine readable instructions and/or to perform some or all of the operations corresponding to the machine readable instructions without executing software or firmware, but other structures are likewise appropriate.

The output switch circuitry 114 has a first set of n input terminals in circuit with the programmable circuitry 104 and second set of n input terminals in circuit with the control circuitry 112. The output switch circuitry 114 also has a first set of n output terminals in circuit with the memory hierarchy 106 and a second set of n output terminals in circuit with the output FIFO buffers 116. The output switch circuitry 114 couples the output terminal of a given instance of the programmable circuitry (e.g., 104A) to either the memory hierarchy 106 or to the corresponding output FIFO buffer (e.g., 116A) based on instructions from the control circuitry 112. The output switch circuitry 114 is described further in connection with FIG. 2B.

In some examples, the compute device 100 includes second means for switching. For example, the second means for switching may be implemented by the output switch circuitry 114.

The output FIFO buffers 116 transfer data and/or instructions from the programmable circuitry 104 to the main memory 102. Accordingly, the compute device 100 implements one output FIFO buffer 116A per instance of programmable circuitry 104A. A given output FIFO buffer 116A refers to a one-dimensional memory unit that temporarily stores data and/or instructions. In this example, the programmable circuitry 104A writes data and/or instructions to the output FIFO buffer 116A in chronological order such that if two values are written into the buffer at T0 and T1 respectively, the main memory 102 reads the value from T0 from the buffer before the value from T1. In other examples, the programmable circuitry 104A reads data and/or instructions from the output buffers 116 using one more techniques different than First In First Out. The output buffers 116 are generally smaller but transfer data faster than the memory hierarchy 106.

Compute-intense read-workloads and compute-intense write-workloads both exhibit performance improvements from data and/or instruction locality as described above. Therefore, compute device 100 includes the memory hierarchy 106 as a first path for both read operations and write operations. However, data and/or instructions from memory-intense write-workloads are not frequently reused by the programmable circuitry 104. Advantageously, the compute device 100 also includes a second path that does not include the memory hierarchy 106 for write operations. When using the foregoing second path for memory-intense write-workloads, the programmable circuitry 104 would ideally transmit data and/or instructions directly to main memory 102 because any intermediate memory structures decrease performance by using additional time and power to perform additional read and write operations. However, in most examples, the main memory 102 reads and the programmable circuitry 104 writes at different speeds and are therefore unable to communicate directly with one another. Thus, like the input FIFO buffers 108 do for read operations, the output FIFIO buffers 116 reconcile the difference in read and write speeds for write operations. The output FIFO buffers 116 thereby make the making the second write-path compatible for communication between the main memory 102 and the programmable circuitry 104 while simultaneously minimizing the number of intermediate memory structures.

The input FIFO buffers 108 and the output FIFO buffers 116 are shown as separate memory structures in the example of FIG. 1. In other examples, a given input FIFO buffer 108A is implemented on the same memory structure (e.g., the same stick of RAM) as a given output FIFO buffer 116A. In such an example, the singular memory structure functionally operates as two separate and independent FIFO buffers as described above. M ore generally, in any of the examples described herein, a given FIFO buffer is used for unidirectional data and/or instruction transfer at any point in time. A given FIFO buffer may therefore be used to implement read operations or write operations but is not used to simultaneously implement both types of operations.

In some examples, the compute device 100 includes third means for data and/or instruction transfer. For example, the third means for data and/or instruction transfer may be implemented by the output FIFO buffers 116.

In the examples of FIGS. 1-6, the input switch circuitry 110 and the output switch circuitry 114 are both in direct communication (e.g., form an electrical connection without any intermediary components) with the programmable circuitry 104. Thus, in this example, a given instance of the programmable circuitry 104A requires only one input terminal and one output terminal (coupled to the input switch circuitry 110 and output switch circuitry 114, respectively) while the main memory is implemented with two output terminals (one coupled to the memory hierarchy 106 and one coupled to the input FIFO buffer 108A) and two input terminals (one coupled to the memory hierarchy 106 and one coupled the output FIFO buffer 116A) to support the programmable circuitry 104A. In other examples, the input switch circuitry 110 and/or the output switch circuitry 114 are implemented in direct communication with the main memory 102 instead of being in direct communication with the programmable circuitry 104. In such examples, a given instance of the programmable circuitry 104A is implemented with two input terminals and/or two output terminals to establish direct communication with a) the memory hierarchy 106 and the input buffer 108A and/or b) the memory hierarchy 106 and the output buffer 116A.

FIG. 2A is a block diagram of an example implementation of the memory hierarchy 106 and the input switch circuitry 110 of FIG. 1. In the example of FIG. 2A, the memory hierarchy 106 includes example Low Level Caches (LLCs) 202A, 202B, 202C, 202D (collectively referred to as LLCs 202), an example Network On a Chip (NOC) 204, example Upper Level Caches (ULCs) 206A, 206B, 206C, 206D (collectively referred to as UL Cs 206). The example of FIG. 2A also shows the input switch circuitry 110 includes example multiplexers 208A, 208B, 208C, and 208D.

Within the memory hierarchy 106, the LLCs 202 form a level of memory that is comparatively close to the main memory 102. In contrast, the ULCs 206 collectively form a level of memory that is comparatively far from the main memory 102. The most frequently used data and/or instructions in a compute-intense workload are therefore stored in the ULCs 206, while less frequently used data and/or instructions in the compute-intense workload are stored in the LLCs 202. FIG. 2A also shows that for data and/or instructions to reach a given ULC 206A, it must first be a) transferred from the main memory 102 to one of the LLCs 202 and b) transferred form the foregoing LLC to the ULC 206A.

The NOC 204 is a communication system that allows the LLCs 202 and the ULCs 206 and to share data amongst each other. For example, suppose data and/or instructions is originally stored in the main memory 102, requested by the programmable circuitry 104A, and subsequently copied to the LLC 202A. Suppose further that the same data and/or instructions is requested from the programmable circuitry 104B after the LLC 202A has been updated. In such an example, the LLC 202A uses the NOC 204 to provide two separate copies of the data and/or instructions to the ULC 206A and the ULC 206B. By providing the ULC 206B with a copy of the data and/or instructions from the LLC 202A, the memory hierarchy 106 does not engage the LLC 202B and therefore saves time and power by skipping an intermediate data and/or instruction transfer. The NOC 204 may be implemented using any suitable communication protocol that meets pre-determined power and latency requirements.

In the example of FIG. 2, the memory hierarchy 106 includes four instances of the LLCs 202 and four instances of the ULCs 206 because n=4 (e.g., there are four instance of the programmable circuitry 104). That is, the example of FIG. 2 shows a 1:1:1 correspondence between the programmable circuitry 104, the LLCs 202, and the ULCs 206. In other examples, the number of LLCs 202 is different from the number of ULCs 206 and instances of programmable circuitry 104. For instance, in some examples, the memory hierarchy 106 does not include the NOC 204 and instead implements one LLC 202 that is shared by all of the ULCs 206.

The memory hierarchy 106 includes two cache levels in the example of FIG. 2. More generally, the memory hierarchy 106 may have any number of cache levels, and any number of disparate upper-level cache structures may share a common LLC structure. Furthermore, the various levels of the memory hierarchy 106 may include any type and amount of volatile memory.

Within the input switch circuitry 110, a given multiplexer 208A has a first input terminal in circuit with the corresponding ULC 206A, a second input terminal in circuit with the corresponding input FIFO buffer 108A, and an output terminal in circuit with the corresponding instance of programmable circuitry 104A. A given multiplexer 208A also has a select terminal in circuit with the control circuitry 112. The control circuitry 112 uses the select terminal to select the state of the multiplexer 208A (e.g., whether the output terminal of the multiplexer 208A is in circuit with its first input terminal or its second input terminal). By doing so, the control circuitry 112 can determine which read-workload path the programmable circuitry 104A, 104B, 104C, 104D instances uses independently of one another. Thus, some instances of the programmable circuitry (e.g., 104A, 104C) can couple to the memory hierarchy 106 and implement compute-intense read-workloads while other instance of the programable circuitry (e.g., 104B, 104D) simultaneously couple to their corresponding input FIFO buffers (e.g., 108B, 108D) and implement memory-intense read-workloads.

In the example of FIG. 2A, the compute device 100 implements a first path for data and/or instruction transfer that goes through each layer of the memory hierarchy 106 and a second path for that goes through a separate intermediate memory structure (the FIFO buffers 108). In other examples, the first and second paths for data and/or instruction transfer share one or more intermediate memory structures between the main memory 102 and the programmable circuitry 104. In such examples, the second path for data and/or instruction transfer starts at the main memory 102, goes through the LLC 202, and then travels to the input switch circuitry 110 instead of going through additional layers of the memory hierarchy 106.

FIG. 2B is a block diagram of an example implementation of the memory hierarchy and the output switch circuitry of FIG. 1. The memory hierarchy 106 includes the same components in the example of FIG. 2B as it does in the example of FIG. 2A. The example of FIG. 2B also shows the output switch circuitry 114 includes example multiplexers 210A, 210B, 210C, and 210D.

Within the output switch circuitry 114, a given multiplexer 210A has a first output terminal in circuit with the corresponding ULC 206A, a second output terminal in circuit with the corresponding output FIFO buffer 116A, and an input terminal in circuit with the corresponding instance of programmable circuitry 104A. A given multiplexer 210A also has a select terminal in circuit with the control circuitry 112. The control circuitry 112 uses the select terminal to select the state of the multiplexer 210A (e.g., whether the output terminal of the multiplexer 210A is in circuit with its first output terminal or its second output terminal). By doing so, the control circuitry 112 can determine which write-workload paths the programmable circuitry 104A, 104B, 104C, 104D instances uses independently of one another. Thus, some instances of the programmable circuitry (e.g., 104B, 104D) can couple to the memory hierarchy 106 and implement compute-intense write-workloads while other instance of the programable circuitry (e.g., 104A, 104C) simultaneously couple to their corresponding output FIFO buffers (e.g., 116A, 116C) and implement memory-intense write-workloads.

Read-workloads and write-workloads can place different types of resource strain on the compute device 100 even if the read-workloads and write-workloads correspond to the same application or use case. For example, the categorization of a read-workload as compute-intense is not indicative of whether a write-workload from the same application or use case is best categorized as compute-intense or memory-intense. Therefore, in some examples, the control circuitry 112 uses a different technique to determine the state of the output switch circuitry 114 than it uses to determine the state of the input switch circuitry 110. Examples of techniques used by the control circuitry 112 to determine a read or write path are described further in connection with FIGS. 4-6.

In the example of FIG. 2B, the compute device 100 implements a first path for data and/or instruction transfer that goes through each layer of the memory hierarchy 106 and a second path for that goes through a separate intermediate memory structure (the FIFO buffers 116). In other examples, the first and second paths for data and/or instruction transfer share one or more intermediate memory structures between the main memory 102 and the programmable circuitry 104. In such examples, the second path for data and/or instruction transfer starts at the programmable circuitry 104, goes through the ULC 206, and then travels to the output switch circuitry 114 instead of going through additional layers of the memory hierarchy 106.

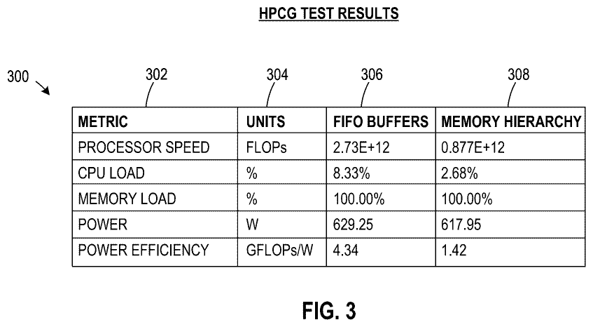

FIG. 3 is an illustrative example of the performance of a device implemented as described in FIG. 1. FIG. 3 shows an example table 300. The table 300 includes example columns 302, 304, 306, and 308.

The columns 302 and 304 show metrics and units, respectively, that are used to quantify the performance of memory-intense workloads. In this example, the memory-intense workloads are High Performance Conjugate Gradients (HPCG), which is a supercomputing benchmark test used in industry. The table 300 reports the processor speed at which the HPCG is executed as measured in Floating Operations Per second (FLOPs). The table 300 also reports CPU load, which is the amount of processing power an instance of programmable circuitry uses to perform the HPCG workload relative to its capacity. The table 300 additionally reports memory load, which is the percentage of a main memory that is being used to execute the HPCG. The table 300 further reports the total amount of power consumed to implement the HPCG workload as measured in Watts (W). Finally, the table 300 reports power efficiency as the ratio of Gigaflops per Watt (GFLOPs/W).

The column 306 shows the values of the metrics in column 302 when the HPCG is implemented using the compute device 100 from the examples described herein. Accordingly, the values of columns 306 show performance when the input switch circuitry 110 routes the memory-intense HPCG read-workloads through the input FIFO buffers 108 and when the output switch circuitry 114 routes the memory-intense HPCG write-workloads through the output FIFO buffers 116. In the example of FIG. 3, the HPCG is implemented on the compute device 100 with a processor speed of approximately 2.73 Teraflops, a CPU load of approximately 8.33%, a memory load of approximately 100%, a total power consumption of approximately 629.25 W, and a power efficiency of approximately 4.34 GFLOPs/W.

The column 308 shows the values of the metrics in column 302 when the HPCG is implemented using a known compute device. In particular, the device of column 308 has the same programmable circuitry 104 and same main memory 102 as the compute device of column 306. However, the compute device of column 308 does not include the input FIFO buffers 108, the input switch circuitry 110, the control circuitry 112, the output switch circuitry 114, or the output FIFO buffers 116. Accordingly, the compute device of column 308 implements the HPCG by routing all read and write operations through a memory hierarchy. In the example of FIG. 3, the HPCG is implemented on the compute device of column 308 with a processor speed of approximately 0.877 Teraflops, a CPU load of approximately 2.68%, a memory load of approximately 100%, a total power consumption of approximately 617.95 W, and a power efficiency of approximately 1.42 GFLOPs/W.

Comparing columns 306 and 308 shows that the input FIFO buffers 108 allow the programmable circuitry 104 in the compute device 100 to access HPG data and/or instructions workload significantly quicker than if the same programmable circuitry was accessing the same HPG data and/or instructions through a memory hierarchy. The quicker access to data allows the compute device 100 to perform more operations per unit of time (as seen in the processor speed metric), thereby also increasing the CPU load and the power efficiency of the compute device 100 relative to the compute device of column 308. More generally, the input FIFO buffers 108 and the output FIFO buffers 116 exhibit performance improvements over the memory hierarchy 106 when the programmable circuitry 104 implements memory-intense workloads as described above.

Flowchart(s) representative of example machine readable instructions, which may be executed by programmable circuitry to implement and/or instantiate the compute device 100 of FIG. 1 and/or representative of example operations which may be performed by programmable circuitry to implement and/or instantiate the compute device 100 of FIG. 1, are shown in FIGS. 4-6. The machine readable instructions may be one or more executable programs or portion(s) of one or more executable programs for execution by programmable circuitry such as the programmable circuitry 912 shown in the example programmable circuitry platform 900 discussed below in connection with FIG. 9 and/or may be one or more function(s) or portion(s) of functions to be performed by the example programmable circuitry (e.g., an FPGA) discussed below in connection with FIGS. 10 and/or 11. In some examples, the machine readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 4-6, many other methods of implementing the example compute device 100 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, a chiplet and/or an array of chiplets, etc.)). As used herein, programmable circuitry includes any type(s) of circuit that may be programmed to perform a desired function such as, for example, a CPU, a core, a chiplet, an array of chiplets, a GPU, a VPU, and/or an FPGA. The programmable circuitry may include one or more CPUs, one or more cores, one or more chiplets, one or more GPUs, one or more VPUs, and/or one or more FPGAs located in the same package (e.g., the same integrated circuit (IC) package or in two or more separate housings), one or more one or more CPUs, one or more cores, one or more chiplets, one or more GPUs, one or more VPUs, and/or one or more FPGAs in a single machine, multiple CPUs, cores, chiplets, GPUs, VPUs, and/or FPGAs distributed across multiple servers of a server rack, and/or multiple CPUs, cores, chiplets, GPUs, VPUs, and/or FPGAs distributed across one or more server racks. Additionally or alternatively, programmable circuitry may include a programmable logic device (PLD), a generic array logic (GAL) device, a programmable array logic (PAL) device, a complex programmable logic device (CPLD), a simple programmable logic device (SPLD), a microcontroller (MCU), a programmable system on chip (PSoC), etc., and/or any combination(s) thereof in any of the contexts explained above.

The machine readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine readable instructions may be fragmented and stored on one or more storage devices, disks and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable, computer readable and/or machine readable media, as used herein, may include instructions and/or program(s) regardless of the particular format or state of the machine readable instructions and/or program(s).

The machine readable instructions described herein can be represented by any past, present, or future instruction language, scripting language, programming language, etc. For example, the machine readable instructions may be represented using any of the following languages: C, C++, Java, C-Sharp, Perl, Python, JavaScript, HyperText Markup Language (HTML), Structured Query Language (SQL), Swift, etc.

As mentioned above, the example operations of FIGS. 4-6 may be implemented using executable instructions (e.g., computer readable and/or machine readable instructions) stored on one or more non-transitory computer readable and/or machine readable media. As used herein, the terms non-transitory computer readable medium, non-transitory computer readable storage medium, non-transitory machine readable medium, and/or non-transitory machine readable storage medium are expressly defined to include any type of computer readable storage device and/or storage disk and to exclude propagating signals and to exclude transmission media. Examples of such non-transitory computer readable medium, non-transitory computer readable storage medium, non-transitory machine readable medium, and/or non-transitory machine readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer-readable instructions, machine-readable instructions, etc.

FIG. 4 is a first flowchart representative of example machine readable instructions and/or example operations 400 that may be executed, instantiated, and/or performed by programmable circuitry to implement a read-workload. While reference is made in the description of FIGS. 4-6 to the programmable circuitry 104A, the examples described in FIGS. 4-6 may additionally or alternatively be implemented to any other instance of the programmable circuitry 104B, 104C, . . . , 104-n. Furthermore, the compute device 110 can implement multiple copies of the logic described in a given flowchart from FIGS. 4-6 in parallel with one another, provided that each copy of the logic corresponds to one instance of the programmable circuitry 104. While reference is made in the description of FIGS. 4-6 to the flow of data, in some examples the flowcharts of FIGS. 4-6 may additionally or alternatively be applied to the flow of instructions as described above.

The example machine-readable instructions and/or operations 400 begin when the control circuitry 112 identifies data to be accessed by the programmable circuitry 104A. (Block 402). The control circuitry 112 may identify the data of block 402 using any suitable technique. In some examples, the control circuitry 112 identifies the data by obtaining a set of instructions (e.g., a program) after a compiler has converted the program from a high-level programming language to a low-level programming language but before the compiler provides the low-level programming language to the programmable circuitry for execution.

The control circuitry 112 determines whether the data of block 402 corresponds to a memory-intense workload. (Block 404). In some examples, the control circuitry 112 makes the determination of block 404 by performing a static code analysis to estimate the amount of times that the program instructs the programmable circuitry 104A to read a value from the same address in main memory 102 more than once. In such examples, the control circuitry 112 determines the data corresponds to a memory-intense workload if the number of times the programmable circuitry 104A rereads a value from main memory 102 is above a threshold (e.g., if the amount of data reusage in the program is sufficiently high). The threshold of block 404 can be determined based on any number of factors, including but not limited to a performance requirement of the workload, a data transfer rate of the memory hierarchy 106, the read speed of programmable circuitry 104A, the write speed of the main memory 102, etc. In other examples, the program includes metadata that self-categorizes one or more workloads as memory-intense or compute-intense. Such metadata may be provided by any source, including but not limited to manual entry from a user, a software application that generated the high-level language instructions, a compiler that converted the high-level language instructions into low-level language instructions, etc.

If the control circuitry 112 determines the data does not correspond to a memory-intense workload (Block 404: No), the data can instead be categorized as compute-intense. Accordingly, in such examples, the control circuitry 112 instructs the main memory 102 (and/or instructs memory controller circuitry associated with the main memory 102) to load the data of block 404 into the memory hierarchy 106. (Block 406).

The control circuitry 112 also instructs the input switch circuitry 110 to couple the programmable circuitry 104A to the memory hierarchy 106 in such examples. (Block 408). The control circuitry 112 implements block 406 by transmitting a value to the select terminal of the multiplexer 208A, thereby causing the multiplexer to 208A to couple the ULC 206A of the memory hierarchy 106 to the input terminal of the programmable circuitry 104.

In some examples, the control circuitry 112 waits until the data is fully or partially loaded into the memory hierarchy 106 at block 406 before changing the state of the input switch circuitry 110 at block 408. In such examples, the control circuitry 112 can preload data for a compute-intense read-workload in the memory hierarchy 106 while the programmable circuitry 104A simultaneously executes a memory-intense workload whose data is flowing through the input FIFO buffer 108A. Such examples may also be referred to as prefetching. In other examples, the control circuitry 112 does not preload data and instead implements block 408 after block 406 without waiting.

Alternatively, if the control circuitry 112 determines the data does correspond to a memory-intense workload (Block 404: Yes), the control circuitry 112 instructs the main memory 102 (and/or instructs memory controller circuitry associated with the main memory 102) to load the data of block 404 into the input FIFO buffer 108A. (Block 410). The control circuitry 112 also instructs the input switch circuitry 110 to couple the programmable circuitry 104A to the input FIFO buffer 108A in such examples. (Block 412). The control circuitry 112 implements block 412 by transmitting a value to the select terminal of the multiplexer 208A, thereby causing the multiplexer to 208A to couple the output terminal of the input FIFO buffer 108A to the input terminal of the programmable circuitry 104.

In some examples, the control circuitry 112 waits to implement block 412 until a threshold amount of data has been loaded into the input FIFO buffer 108A at block 410, thereby preventing or delaying the programmable circuitry 104A from outpacing the main memory 102 and emptying the input FIFO buffer 108A. Similarly, in some examples, the control circuitry 112 preloads/prefetches data into the input FIFO buffer 108A while the programmable circuitry 104A simultaneously executes a compute-intense workload whose data is flowing through the memory hierarchy 106.

After the control circuitry 112 uses the programmable circuitry 104A to either the memory hierarchy 106 (Block 408) or the input FIFO buffer 108A (Block 412), the programmable circuitry 104 begins accessing data and performing operations on it. (Block 414). The operations may correspond to any use case or application. The path used to access data at block 414 is dependent on the categorization of the data as a memory-intense or compute-intense workload, thereby ensuring that the programmable circuitry 104A can execute both kinds of workloads at a high performance metrics.

The control circuitry 112 determines whether to identify more data. (Block 416). If the control circuitry 112 does identify more data (Block 416: Yes), control returns to block 404 where the control circuitry 112 determines whether the additional data corresponds to a memory-intense workload. Alternatively, if the control circuitry 112 does not identify more data (Block 416: No), the machine-readable instructions and/or operations 400 end.

In the example of FIG. 4, the control circuitry 112 analyzes data from a first workload at block 404 and then waits analyze a second workload at block 404 at least until the programmable circuitry 104A begins performance of the first workload at block 414. In other examples, the control circuitry 112 analyzes multiple workloads at block 404 before any operations are performed at block 414. In such examples, the control circuitry 112 identifies opportunities to preload data (e.g., a compute-intense workload immediately follows a memory-intense workload, or vice versa) and does so by implanting another iteration of block 406 or block 410 before the operations at the previous iteration of block 414 have completed. M ore generally, in some examples, the compute device 100 implements one or more of blocks 402-416 concurrently with one another to improve performance.

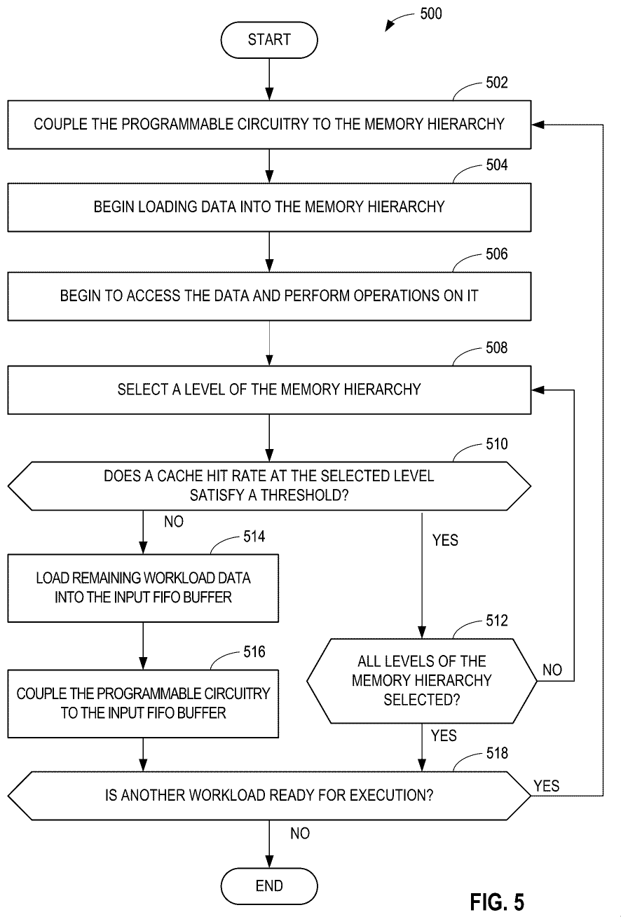

FIG. 5 is a second flowchart representative of example machine readable instructions and/or example operations 500 that may be executed, instantiated, and/or performed by programmable circuitry to implement a read-workload. In the example of FIG. 5, workloads are initially presumed to be compute-intense. Accordingly, the machine readable instructions and/or operations 500 begin when the control circuitry 112 instructs the input switch circuitry 110 to couple the programmable circuitry 104A to the memory hierarchy 106. (Block 502). The main memory 102 then begins loading data into the memory hierarchy 106. (Block 504). In other examples, the compute device 100 implements block 504 before 502.

Once the programmable circuitry 104A is connected to the memory hierarchy 106 and data has started to flow into the memory hierarchy 106, the programmable circuitry 104A can begin to access the data and perform operations on it. (Block 506). The operations may correspond to any use case or application.

In parallel with the execution of the read-workload at block 506, the control circuitry 112 selects a level of the memory hierarchy 106. (Block 508). The control circuitry 112 then determines whether a cache hit rate at the selected level satisfies a threshold. (Block 510). In general, a cache request refers to when a given memory structure within the memory hierarchy 106 receives a request for data. The response of the memory structure to the cache request is either a cache hit or a cache miss. A cache hit describes an example where the memory structure is storing (and can therefore immediately provide) the relevant data upon receipt of the cache request. In contrast, a cache miss describes an example where the memory structure is not storing the relevant data upon receipt of the cache request. In such examples, the memory structure must use additional time and power to obtain the foregoing data by a) sending a new cache request to a lower level cache or b) obtaining the data directly from the main memory 102. Finally, a cache hit rate refers to a ratio of cache hits to total cache requests that a memory structure receives for a given workload. Thus, cache hit rates generally increase with the frequency at which data is reused by the programmable circuitry 104A.

In this example, a threshold is satisfied at block 510 if the cache hit rate is greater or equal to a pre-determined percentage value. Notably, a designer or manufacturer of the compute device 100 may select different threshold percentages for different memory levels so that each threshold percentage can best describe the expected performance of the corresponding memory level. In examples where there are multiple memory structures in a single memory level (e.g., FIGS. 2A and 2B), the control circuitry 112 only evaluates the cache hit rate of the memory structure that corresponds to the programmable circuitry 104A (e.g., the LLC 202A or the ULC 206A). In doing so, the control circuitry 112 minimizes the extent to which the properties of a workload being performed by a different instance of the programmable circuitry (e.g. 104B) influences the analysis of the workload being performed by the programmable circuitry 104A.

If the cache hit rate at the selected level satisfies the corresponding threshold (Block 510: Yes), the control circuitry 112 determines whether all levels of the memory hierarchy 106 have been selected. (Block 512). If one or more levels have not been selected (Block 512: No), control returns block 508 where the control circuitry 112 selects a level that has not been previously selected during the execution of the current workload of block 506. Alternatively, if all the memory levels have been selected during the current workload and all their cache hit rates satisfy the corresponding thresholds (Block 512: Yes), control proceeds to block 514.

If the cache hit rate at the selected level does not satisfy the threshold (Block 510: No), then the memory hierarchy 106 is not performing at a sufficient quality to support the presumption that the workload is compute-intense. Instead, the control circuitry 112 recategorizes the workload as memory-intense. To implement the recategorization, the control circuitry 112 instructs the main memory 102 (and/or instructs memory controller circuitry associated with the main memory 102) to load any remaining data that corresponds to the current workload of block 504 into the input FIFO buffer 108A. (Block 514). The control circuitry 112 also instructs the main memory 102 at block 514 to stop loading the foregoing remaining data into the memory hierarchy 106.

The control circuitry 112 instructs the input switch circuitry 110 to couple the programmable circuitry 104A to the input FIFO buffer 108A. (Block 516). In some examples, the control circuitry 112 waits to implement block 510 until the programmable circuitry 104 has accessed the rest of the data in the memory hierarchy 106 that corresponds to the current workload of block 504. In other examples, the control circuitry 112 couples the programmable circuitry 104A to the input FIFO buffer 108A at block 516 immediately after the input FIFO buffer 108A has been sufficiently loaded at block 514. In such examples, the control circuitry 112 instructs the main memory 102 to identify any data in the memory hierarchy 106 that corresponds to the current workload and to copy said data into the input FIFO buffer 108A.

The control circuitry 112 determines whether another workload is available for execution. (Block 518). If the control circuitry 112 does identify another workload (Block 518: Yes), control returns to block 502 where the control circuitry 112 couples the programmable circuitry 104A to the memory hierarchy 106. Alternatively, if the control circuitry 112 does not identify another workload (Block 518: No), the machine-readable instructions and/or operations 500 end.

In the example of FIG. 5, the control circuitry 112 implements blocks 514 and 516 based on a determination that one or more cache hit rates fail to satisfy their respective thresholds. In other examples, the control circuitry 112 implements blocks 514 and 516 based on a determination that one or more different utilization metrics of the memory hierarchy 106 are insufficient.

The flowchart of FIG. 4 describes an example where the control circuitry 112 categorizes a workload as compute-intense or memory-intense by estimating the properties of the workload before runtime (e.g., before the workload is executed by the programmable circuitry 104A). In contrast, the flowchart of FIG. 5 describes an example where the control circuitry 112 categorizes a workload as compute-intense or memory-intense by measuring utilization metrics of the memory hierarchy 106 during runtime (e.g., while the workload is being executed). Advantageously, a manufacturer or designer can use one or both of the techniques described in FIGS. 4 and 5 to implement the compute device 100. A decision of which of the foregoing techniques to use may be based on any number of factors, including but not limited to the performance requirements of the use case, the speed and accuracy of cache hit measurement circuitry, the computational resources available to perform a static code analysis, etc.

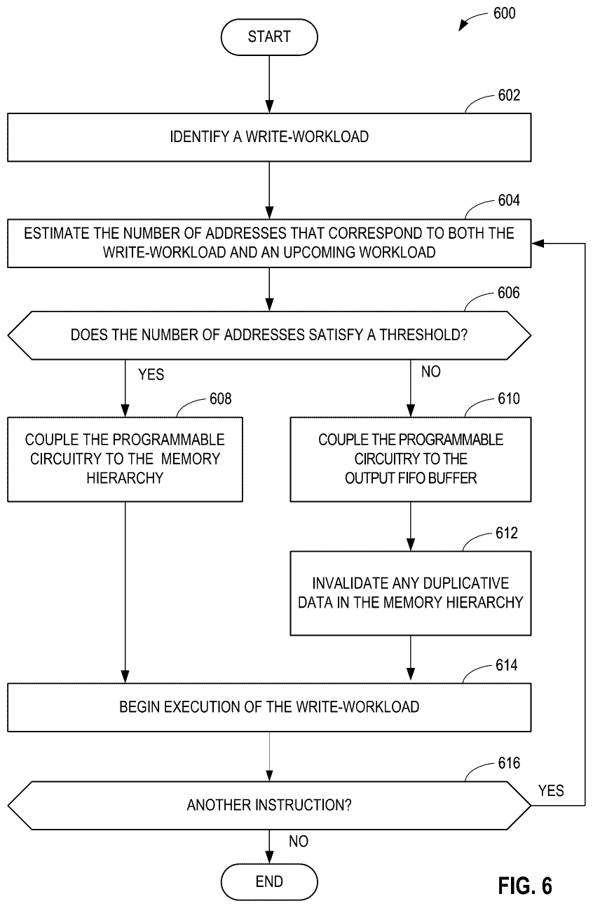

FIG. 6 is a flowchart representative of example machine readable instructions and/or example operations 600 that may be executed, instantiated, and/or performed by example programmable circuitry to implement a write-workload. The machine readable instructions and/or operations 600 begin when the control circuitry 112 identifies a write-workload. (Block 602). A write-workload refers to the transfer of data from the programmable circuitry 104A to the main memory 102 as described above. The control circuitry 112 may identify the foregoing data using any suitable technique. In some examples, the control circuitry 112 identifies the data by obtaining a set of instructions (e.g., a program) after a compiler has converted the program from a high-level programming language to a low-level programming language but before the compiler provides the low-level programming language to the programmable circuitry for execution.

The control circuitry 112 estimates the number of memory addresses that correspond to both the current write-workload and an upcoming workload. (Block 604). The upcoming workload may be either a read-workload or a write-workload because either operation constitutes reuse of the data. For example, if the program causes the programmable circuitry 104A to a) update a value in a memory address and b) read a value from the same memory address shortly thereafter, then the updated value is preferably stored at or near the highest level of the memory hierarchy so it can be quickly retrieved when needed. Similarly, if the programmable circuitry to a) write a value to a memory address and b) overwrite the same memory address with a new value shortly thereafter. The first value is preferably stored at or near the at or near the highest level of the memory hierarchy so it can be quickly rewritten when needed. In contrast, if an address being updated in the current write-workload does not correspond to an upcoming workload, the new value of the address is preferably written directly to the main memory 102 to avoid the intermediate data transfers of the memory hierarchy 106.

The control circuitry 112 determines whether the number of addresses estimated at block 604 satisfies a threshold. (Block 606). The threshold of block 606 can be determined based on any number of factors, including but not limited to a performance requirement of the workload, a data transfer rate of the memory hierarchy 106, the write speed of programmable circuitry 104A, the read speed of the main memory 102, etc. If the number of addresses satisfies the threshold, the write-workload of block 602 is considered compute-intense. In such examples, the control circuitry 112 instructs the output switch circuitry 114 to couple the output terminal of the programmable circuitry 104A to the memory hierarchy 106. (Block 608). Control proceeds to block 614 after block 608.

Alternatively, if the control circuitry 112 determines the number of addresses does not satisfy the threshold, the write-workload of block 602 is considered memory-intense. In such examples, the control circuitry 112 instructs the output switch circuitry 114 to couple the output terminal of the programmable circuitry 104A to the output FIFO buffer 116A. (Block 610).

After connecting the programmable circuitry 104A to the output FIFO buffer 116A, the control circuitry 112 invalidates any duplicative data that may exist in the memory hierarchy. (Block 612). For example, suppose the programmable circuitry 104A accesses the value of an address through the memory hierarchy 106 and then overwrites the value via the output FIFO buffer 116A. If any of memory structures in the memory hierarchy 106 still have a copy of the original value when the overwrite occurs through the output FIFO buffer 116A, the original value becomes duplicative and incorrect. Moreover, if the programable circuitry 104A later attempts to perform a read operation on the same address, the memory hierarchy 106 may inadvertently provide the incorrect original value and cause the programmable circuitry 104A to commit an error. Thus, by invaliding the duplicative data in the memory hierarchy 106 at block 612, the control circuitry 112 a) prevents the memory hierarchy 106 from providing the original value to the programmable circuitry 104A and b) authorizes the memory hierarchy 106 to overwrite the original value with new data from the main memory 102. In some examples the operations at block 612 are referred to as, or are part of, a cache coherency protocol.

After either of blocks 608 or 612, the programmable circuitry 104A begins execution of the write-workload. (Block 614). To do so, the programmable circuitry 104A writes values to either the memory hierarchy 106 or the output FIFO buffer 116A based on the status of the multiplexer 210A within the output switch circuitry 114.

The control circuitry 112 determines whether there is another write-workload. (Block 616). If there is another write-workload (Block 616: Yes), control returns to block 604 where the control circuitry 112 estimates the number of memory addresses that correspond to both the new write-workload and an upcoming workload. Alternatively, if no further write-workloads are available (Block 616: No), the machine readable instructions and/or operations 600 end.

FIGS. 7, 8A, 8B, and 9 include example computing architectures in which any of the techniques and configurations above may be implemented.

FIG. 7 illustrates an example hardware arrangement of an example data center 700 used to provide multiple examples or instances of a computing system (e.g., the programmable circuitry platform 900, described below), with each example of the computing system identified as a respective platform (e.g., the platform 730, described below). The data center 700 includes example data center infrastructure 701, an example data center network fabric 702, and an example power distribution unit 703 to support multiple racks of compute platforms, with a single instance of an example rack 710 depicted. The data center infrastructure 701 may provide physical components that host the compute platform hardware, storage components, and/or networking equipment. The data center network fabric 702 may include switches and/or networking components to support data flows among various compute platforms and storage devices throughout the data center. The power distribution unit 703 may include components to distribute and/or control power among the various compute platforms, networking, and storage devices.

The rack 710 of FIG. 7 includes, but is not limited to, example cooling infrastructure 711, an example network interface 712, and/or other related physical components to support discrete instances of multiple chassis. The rack 710 provides power, connectivity, and/or cooling to each of the multiple chassis in a single rack, with a single instance of a chassis 720 in the example of in FIG. 7. The chassis 720 includes, but is not limited to, example cooling infrastructure 721, an example chassis network fabric 722, and an example power supply 723, which provides cooling, network connectivity, and/or power to multiple platforms within the chassis. Although a single instance of an example platform 730 is illustrated in FIG. 7, in some examples, a common data center rack configuration may include dozens of chassis, with each chassis to support a number of platforms depending on the physical size of the platform hardware and/or supporting equipment.

The platform 730 of FIG. 7 may be referred to as a server or node, depending on the use case for the platform 730 and the data center 700. The platform 730 includes but is not limited to examples of a discrete computing system hosted on a single board. In FIG. 7, the platform 730 is illustrated as hosting a first example chip assembly 740A and a second example chip assembly 740B on a first board provided by a printed circuitry board (PCB) or other platform board, shown as an example PCB 731. In some examples, the platform 730 may include only one chip package, whereas the PCB 731 includes interconnection of multiple chip assemblies via an interface (e.g., a peripheral component intercouple express (PCIe) interface). Additional chip packages and components may also be hosted on the PCB 731.

Some examples of the chip assembly 740A, 740B of FIG. 7 may be termed as a System-on-Chip (SoC) package, as modular chiplets that perform different functions are integrated into a single package—even though this chip package is composed of multiple dies unlike a traditional SoC design that uses a single die. Other examples of the chip assembly 740A, 740B may include a System-on-Package (SoP), System-in-a-Package (SiP), or other single chip packages. Various combinations of 2 dimension (D), 2.5D, and/or 3D packaging technologies may be used to manufacture and/or assemble the chip package and its underlying structure. Additionally, different manufacturing processes may be used to provide chiplets and components from different process nodes (e.g., semiconductor fabrication systems).

The first chip assembly 740A and the second chip assembly 740B of FIG. 7 are packages that include multiple chiplets and/or dies for respective functions, such as separate chiplets for processing (e.g., central processing unit (CPU) or graphical processing unit (GPU) chiplets), memory (e.g., cache or high-bandwidth memory chiplets), input/output (I/O) (e.g., I/O chiplets), acceleration (e.g., artificial intelligence (AI)/machine learning (ML) acceleration chiplets), signal processing (e.g., audio or video processing chiplets), etc. The close-up of chip assembly 740A of FIG. 7 includes a I/O Hub chiplet 741, chiplets 742, and a power supply 743. These components may be hosted on an interposer that is designed to couple multiple dies and/or components within a single semiconductor package (e.g., chip package). In some examples, the chiplets 742 may be manufactured and/or sourced separately and later assembled into the chip package to create the chip assembly 740A. Various connections may be provided among the chiplets 742, such as with the use of Universal Chiplet Intercouple Express (UCle) interfaces and communications, and/or between chiplets and on-chip memory (e.g., high-bandwidth memory (HBM)) using HBM3 (JEDEC), Universal Memory Interface (UMI), or other memory interfaces.

FIG. 8A illustrates an example arrangement of an example chip assembly 840A (e.g., a multi-processing core example of the first chip assembly 740A or the second chip assembly 740B of FIG. 7), with expanded views of the chiplets and processing units included herein. In FIG. 8A the chip assembly 840A, which may constitute a SoC, SoP, SiP, and/or other type of chip package, includes chiplets such as an example chiplet 810A, an example chiplet 810B, etc. and associated on-package memory (e.g., high-speed memory) such as 3D-stacked, High Bandwidth Memory (HBM) instances (shown as an example HBM 820A, an example HBM 820B, interfaces (e.g., UCle interfaces) shown as an example UCle 821A, an example UCle 821B, and an example I/O hub 830 (e.g., which may be implemented by a I/O chiplet). Other hardware elements of a chip package are not included for simplicity. Although the examples disclosed herein are described in conjunction with UCLe interfaces, one or more of the interfaces may be device-to-device (Dev2Dev) interfaces (e.g., CXLI, peripheral component intercouple express (PCIE)), die to die (D2D) interfaces (e.g., NVLINK), chiplet to chiplet (Ch2Ch) interfaces (e.g., universal chiplet interconnected express (UCle)), core to core (C2C) interfaces (e.g., using coherency protocols), etc.

The chiplets 810A, 810B of FIG. 8A include multiple processing units and the example processing units 800A, 800B, 800C, 800D include one or multiple cores, respectively. For example, the chiplet 810A of FIG. 8A includes four processing units (the processing units 800A, 800B, 800C, 800D) and an example Level 3 (L3) cache 804. The processing units 800A, 800B, 800C, 800D may include one or multiple processing cores, one or multiple caches, other processing units and/or passive and/or active elements. For example, processing unit 800A includes two cores (an example core 801A and an example core 801B), vector processing unit 802, and an example level 2 (L2) cache 803. Accordingly, a single-core processing unit can provide four cores per chiplet and eight total cores in a two-chiplet chip assembly, whereas a dual-core processing unit can provide eight cores per chiplet and sixteen total cores in a two-chiplet chip assembly. However, examples disclosed herein may correspond to other permutations.

FIG. 8B is an example arrangement of an example chip assembly 840B (e.g., a multi-chiplet high-performance computing (HPC) example of chip assembly 740A, 740B), adapted for HPC applications (e.g., parallel processing operations involving thousands, millions, or more of processors and/or cores operating simultaneously). The example chip assembly 840B illustrates placement as a SiP, SoC, and/or other package onto a platform board (e.g., the PCB 731 of FIG. 7). The platform board may be in a data center (e.g., the data center 700 of FIG. 7) or in a standalone deployment setting (e.g., in a standalone computer system, mobile computing device, autonomous device, etc.).

The chip assembly 840B of FIG. 8B is composed of multiple chiplets, shown with four chiplets, including example chiplets 810C, 810D, 810E, 810F. The chiplets 810C, 810D, 810E, 810F include multiple processing units, such as thirty two processing units with a corresponding level 3 (L3) cache for each processing unit. The processing units may include one or multiple cores, such as an example single-core processing unit 800E shown as part of the chiplet 810C. The chip assembly 840B also includes corresponding memory resources, such as HBM elements corresponding to respective banks of processing units (e.g., HBM 820B and HBM 820C corresponding respective sets of processing units of chiplet 810C), UCle interfaces, and/or an IO Hub.

The chip assembly and related products or devices described herein may be configured in a variety of computing system examples. Such examples include non-transitory machine-readable media storing machine-readable instructions and one or more processors in circuit with the memory, such that executing the machine-readable instructions configure one or more of the processors and/or implementing hardware (e.g., the processing unit 800, the chiplet 810, the chip 740, and/or the platform 730 of FIGS. 7, 8A, and/or 8B) to perform operations described above for electronic systems or devices (e.g., to perform data and/or instruction transfer, etc.). It should be further understood that software, including one or more machine readable instructions, that facilitate processing and operations as described above may be distributed, installed, or otherwise provided to networked devices (e.g., servers or cloud computing systems). Alternatively, in some examples, the software may be obtained and loaded (or, re-loaded/upgraded) from one or more servers and/or cloud computing systems, such as software stored on a server for distribution over the Internet, for example.

FIG. 9 is a block diagram of an example programmable circuitry platform 900 structured to execute and/or instantiate the example machine-readable instructions and/or the example operations of FIGS. 4-6 to implement the compute device 100 of FIGS. 1-2B. The programmable circuitry platform 900 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 900 of the illustrated example includes programmable circuitry 912. The programmable circuitry 912 of the illustrated example is hardware. For example, the programmable circuitry 912 can be implemented by one or more integrated circuits, logic circuits, chiplets, cores, FPGAS, microprocessors, CPUs, GPUs, VPUs, DSPs, and/or microcontrollers from any desired family or manufacturer. The programmable circuitry 912 may be implemented by one or more semiconductor based (e.g., silicon based) devices. In this example, the programmable circuitry 912 implements the programmable circuitry 104 and the control circuitry 112.

The programmable circuitry 912 of the illustrated example includes a local memory 913 (e.g., a cache, registers, etc.). The programmable circuitry 912 of the illustrated example is in communication with memory 914, 916, which includes a volatile memory 914 and a non-volatile memory 916, by a bus 918. The volatile memory 914 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 916 may be implemented by flash memory and/or any other desired type of memory device. Access to the memory 914, 916 of the illustrated example is controlled by a memory controller 917. In some examples, the memory controller 917 may be implemented by one or more integrated circuits, logic circuits, microcontrollers from any desired family or manufacturer, or any other type of circuitry to manage the flow of data going to and from the memory 914, 916.

The programmable circuitry platform 900 of the illustrated example also includes interface circuitry 920. The interface circuitry 920 may be implemented by hardware in accordance with any type of interface standard, such as an Ethernet interface, a universal serial bus (USB) interface, a Bluetooth® interface, a near field communication (NFC) interface, a Peripheral Component Intercouple (PCI) interface, and/or a Peripheral Component Intercouple Express (PCIe) interface.

In the illustrated example, one or more input devices 922 are connected to the interface circuitry 920. The input device(s) 922 permit(s) a user (e.g., a human user, a machine user, etc.) to enter data and/or commands into the programmable circuitry 912. The input device(s) 922 can be implemented by, for example, an audio sensor, a microphone, a camera (still or video), a keyboard, a button, a mouse, a touchscreen, a trackpad, a trackball, an isopoint device, and/or a voice recognition system.

One or more output devices 924 are also connected to the interface circuitry 920 of the illustrated example. The output device(s) 924 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 920 of the illustrated example, thus, typically includes a graphics driver card, a graphics driver chip, and/or graphics processor circuitry such as a GPU.

The interface circuitry 920 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 926. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 900 of the illustrated example also includes one or more mass storage discs or devices 928 to store firmware, software, and/or data. Examples of such mass storage discs or devices 928 include magnetic storage devices (e.g., floppy disk, drives, HDDs, etc.), optical storage devices (e.g., Blu-ray disks, CDs, DV Ds, etc.), RAID systems, and/or solid-state storage discs or devices such as flash memory devices and/or SSDs.

The machine readable instructions 932, which may be implemented by the machine readable instructions of FIGS. 4-6, may be stored in the mass storage device 928, in the volatile memory 914, in the non-volatile memory 916, and/or on at least one non-transitory computer readable storage medium such as a CD or DVD which may be removable. In this example, the volatile memory 916 implements the main memory 102, the memory hierarchy 106, the input FIFO buffers 108, and the output FIFO buffers 116.

FIG. 10 is a block diagram of an example implementation of the programmable circuitry 912 of FIG. 9. In this example, the programmable circuitry 912 of FIG. 9 is implemented by a microprocessor 1000. For example, the microprocessor 1000 may be a general-purpose microprocessor (e.g., general-purpose microprocessor circuitry). The microprocessor 1000 executes some or all of the machine-readable instructions of the flowcharts of FIGS. 4-6 to effectively instantiate the circuitry of FIGS. 1-2B as logic circuits to perform operations corresponding to those machine readable instructions. In some such examples, the circuitry of FIGS. 1-2B is instantiated by the hardware circuits of the microprocessor 1000 in combination with the machine-readable instructions. For example, the microprocessor 1000 may be implemented by multi-core hardware circuitry such as a CPU, a DSP, a GPU, a VPU, an XPU, etc. Although it may include any number of example cores 1002 (e.g., 1 core), the microprocessor 1000 of this example is a multi-core semiconductor device including N cores. The cores 1002 of the microprocessor 1000 may operate independently or may cooperate to execute machine readable instructions. For example, machine code corresponding to a firmware program, an embedded software program, or a software program may be executed by one of the cores 1002 or may be executed by multiple ones of the cores 1002 at the same or different times. In some examples, the machine code corresponding to the firmware program, the embedded software program, or the software program is split into threads and executed in parallel by two or more of the cores 1002. The software program may correspond to a portion or all of the machine readable instructions and/or operations represented by the flowcharts of FIGS. 4-6.

The cores 1002 may communicate by a first example bus 1004. In some examples, the first bus 1004 may be implemented by a communication bus to effectuate communication associated with one(s) of the cores 1002. For example, the first bus 1004 may be implemented by at least one of an Inter-Integrated Circuit (I2C) bus, a Serial Peripheral Interface (SPI) bus, a PCI bus, or a PCIe bus. Additionally or alternatively, the first bus 1004 may be implemented by any other type of computing or electrical bus. The cores 1002 may obtain data, instructions, and/or signals from one or more external devices by example interface circuitry 1006. The cores 1002 may output data, instructions, and/or signals to the one or more external devices by the interface circuitry 1006. Although the cores 1002 of this example include example local memory 1020 (e.g., Level 1 (L1) cache that may be split into an L1 data cache and an L1 instruction cache), the microprocessor 1000 also includes example shared memory 1010 that may be shared by the cores (e.g., Level 2 (L2 cache)) for high-speed access to data and/or instructions. Data and/or instructions may be transferred (e.g., shared) by writing to and/or reading from the shared memory 1010. The local memory 1020 of each of the cores 1002 and the shared memory 1010 may be part of a hierarchy of storage devices including multiple levels of cache memory and the main memory (e.g., the memory 914, 916 of FIG. 9). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1002 may be referred to as a CPU, DSP, GPU, etc., or any other type of hardware circuitry. Each core 1002 includes control unit circuitry 1014, arithmetic and logic (AL) circuitry (sometimes referred to as an ALU) 1016, a plurality of registers 1018, the local memory 1020, and a second example bus 1022. Other structures may be present. For example, each core 1002 may include vector unit circuitry, single instruction multiple data (SIMD) unit circuitry, load/store unit (LSU) circuitry, branch/jump unit circuitry, floating-point unit (FPU) circuitry, etc. The control unit circuitry 1014 includes semiconductor-based circuits structured to control (e.g., coordinate) data movement within the corresponding core 1002. The AL circuitry 1016 includes semiconductor-based circuits structured to perform one or more mathematic and/or logic operations on the data within the corresponding core 1002. The AL circuitry 1016 of some examples performs integer based operations. In other examples, the AL circuitry 1016 also performs floating-point operations. In yet other examples, the AL circuitry 1016 may include first AL circuitry that performs integer-based operations and second AL circuitry that performs floating-point operations. In some examples, the AL circuitry 1016 may be referred to as an Arithmetic Logic Unit (ALU).

The registers 1018 are semiconductor-based structures to store data and/or instructions such as results of one or more of the operations performed by the AL circuitry 1016 of the corresponding core 1002. For example, the registers 1018 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1018 may be arranged in a bank as shown in FIG. 10. Alternatively, the registers 1018 may be organized in any other arrangement, format, or structure, such as by being distributed throughout the core 1002 to shorten access time. The second bus 1022 may be implemented by at least one of an I2C bus, a SPI bus, a PCI bus, or a PCIe bus.

Each core 1002 and/or, more generally, the microprocessor 1000 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1000 is a semiconductor device fabricated to include many transistors interconnected to implement the structures described above in one or more integrated circuits (ICs) contained in one or more packages.

The microprocessor 1000 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those discussed herein. A GPU, DSP and/or other programmable device can also be an accelerator. Accelerators may be on-board the microprocessor 1000, in the same chip package as the microprocessor 1000 and/or in one or more separate packages from the microprocessor 1000.

FIG. 11 is a block diagram of another example implementation of the programmable circuitry 912 of FIG. 9. In this example, the programmable circuitry 912 is implemented by FPGA circuitry 1100. For example, the FPGA circuitry 1100 may be implemented by an FPGA. The FPGA circuitry 1100 can be used, for example, to perform operations that could otherwise be performed by the example microprocessor 1000 of FIG. 10 executing corresponding machine readable instructions. However, once configured, the FPGA circuitry 1100 instantiates the operations and/or functions corresponding to the machine readable instructions in hardware and, thus, can often execute the operations/functions faster than they could be performed by a general-purpose microprocessor executing the corresponding software.

More specifically, in contrast to the microprocessor 1000 of FIG. 10 described above (which is a general purpose device that may be programmed to execute some or all of the machine readable instructions represented by the flowchart(s) of FIGS. 4-6 but whose interconnections and logic circuitry are fixed once fabricated), the FPGA circuitry 1100 of the example of FIG. 11 includes interconnections and logic circuitry that may be configured, structured, programmed, and/or interconnected in different ways after fabrication to instantiate, for example, some or all of the operations/functions corresponding to the machine readable instructions represented by the flowchart(s) of FIGS. 4-6. In particular, the FPGA circuitry 1100 may be thought of as an array of logic gates, interconnections, and switches. The switches can be programmed to change how the logic gates are interconnected by the interconnections, effectively forming one or more dedicated logic circuits (unless and until the FPGA circuitry 1100 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 4-6. As such, the FPGA circuitry 1100 may be configured and/or structured to effectively instantiate some or all of the operations/functions corresponding to the machine readable instructions of the flowchart(s) of FIGS. 4-6 as dedicated logic circuits to perform the operations/functions corresponding to those software instructions in a dedicated manner analogous to an ASIC. Therefore, the FPGA circuitry 1100 may perform the operations/functions corresponding to the some or all of the machine readable instructions of FIGS. 4-6 faster than the general-purpose microprocessor can execute the same.

In the example of FIG. 11, the FPGA circuitry 1100 is configured and/or structured in response to being programmed (and/or reprogrammed one or more times) based on a binary file. In some examples, the binary file may be compiled and/or generated based on instructions in a hardware description language (HDL) such as Lucid, Very High Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 1100 of FIG. 11 may access and/or load the binary file to cause the FPGA circuitry 1100 of FIG. 11 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1100 of FIG. 11 to cause configuration and/or structuring of the FPGA circuitry 1100 of FIG. 11, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1100 of FIG. 11 may access and/or load the binary file to cause the FPGA circuitry 1100 of FIG. 11 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1100 of FIG. 11 to cause configuration and/or structuring of the FPGA circuitry 1100 of FIG. 11, or portion(s) thereof.

The FPGA circuitry 1100 of FIG. 11, includes example input/output (I/O) circuitry 1102 to obtain and/or output data to/from example configuration circuitry 1104 and/or external hardware 1106. For example, the configuration circuitry 1104 may be implemented by interface circuitry that may obtain a binary file, which may be implemented by a bit stream, data, and/or machine-readable instructions, to configure the FPGA circuitry 1100, or portion(s) thereof. In some such examples, the configuration circuitry 1104 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1106 may be implemented by external hardware circuitry. For example, the external hardware 1106 may be implemented by the microprocessor 1000 of FIG. 10.

The FPGA circuitry 1100 also includes an array of example logic gate circuitry 1108, a plurality of example configurable interconnections 1110, and example storage circuitry 1112. The logic gate circuitry 1108 and the configurable interconnections 1110 are configurable to instantiate one or more operations/functions that may correspond to at least some of the machine readable instructions of FIGS. 4-6 and/or other desired operations. The logic gate circuitry 1108 shown in FIG. 11 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1108 to enable configuration of the electrical structures and/or the logic gates to form circuits to perform desired operations/functions. The logic gate circuitry 1108 may include other electrical structures such as look-up tables (LUTs), registers (e.g., flip-flops or latches), multiplexers, etc.

The configurable interconnections 1110 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1108 to program desired logic circuits.

The storage circuitry 1112 of the illustrated example is structured to store result(s) of the one or more of the operations performed by corresponding logic gates. The storage circuitry 1112 may be implemented by registers or the like. In the illustrated example, the storage circuitry 1112 is distributed amongst the logic gate circuitry 1108 to facilitate access and increase execution speed.

The example FPGA circuitry 1100 of FIG. 11 also includes example dedicated operations circuitry 1114. In this example, the dedicated operations circuitry 1114 includes special purpose circuitry 1116 that may be invoked to implement commonly used functions to avoid the need to program those functions in the field. Examples of such special purpose circuitry 1116 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1100 may also include example general purpose programmable circuitry 1118 such as an example CPU 1120 and/or an example DSP 1122. Other general purpose programmable circuitry 1118 may additionally or alternatively be present such as a GPU, an XPU, etc., that can be programmed to perform other operations.

Although FIGS. 10 and 11 illustrate two example implementations of the programmable circuitry 912 of FIG. 9, many other approaches are contemplated. For example, FPGA circuitry may include an on-board CPU, such as one or more of the example CPU 1120 of FIG. 10. Therefore, the programmable circuitry 912 of FIG. 9 may additionally be implemented by combining at least the example microprocessor 1000 of FIG. 10 and the example FPGA circuitry 1100 of FIG. 11. In some such hybrid examples, one or more cores 1002 of FIG. 10 may execute a first portion of the machine readable instructions represented by the flowchart(s) of FIGS. 4-6 to perform first operation(s)/function(s), the FPGA circuitry 1100 of FIG. 11 may be configured and/or structured to perform second operation(s)/function(s) corresponding to a second portion of the machine readable instructions represented by the flowcharts of FIGS. 4-6, and/or an ASIC may be configured and/or structured to perform third operation(s)/function(s) corresponding to a third portion of the machine readable instructions represented by the flowcharts of FIGS. 4-6.

It should be understood that some or all of the circuitry of FIGS. 1-2B may, thus, be instantiated at the same or different times. For example, same and/or different portion(s) of the microprocessor 1000 of FIG. 10 may be programmed to execute portion(s) of machine-readable instructions at the same and/or different times. In some examples, same and/or different portion(s) of the FPGA circuitry 1100 of FIG. 11 may be configured and/or structured to perform operations/functions corresponding to portion(s) of machine-readable instructions at the same and/or different times.

In some examples, some or all of the circuitry of FIGS. 1-2B may be instantiated, for example, in one or more threads executing concurrently and/or in series. For example, the microprocessor 1000 of FIG. 10 may execute machine readable instructions in one or more threads executing concurrently and/or in series. In some examples, the FPGA circuitry 1100 of FIG. 11 may be configured and/or structured to carry out operations/functions concurrently and/or in series. Moreover, in some examples, some or all of the circuitry of FIGS. 1-2B may be implemented within one or more virtual machines and/or containers executing on the microprocessor 1000 of FIG. 10.

In some examples, the programmable circuitry 912 of FIG. 9 may be in one or more packages. For example, the microprocessor 1000 of FIG. 10 and/or the FPGA circuitry 1100 of FIG. 11 may be in one or more packages. In some examples, an XPU may be implemented by the programmable circuitry 912 of FIG. 9, which may be in one or more packages. For example, the XPU may include a CPU (e.g., the microprocessor 1000 of FIG. 10, the CPU 1120 of FIG. 11, etc.) in one package, a DSP (e.g., the DSP 1122 of FIG. 11) in another package, a GPU in yet another package, and an FPGA (e.g., the FPGA circuitry 1100 of FIG. 11) in still yet another package.

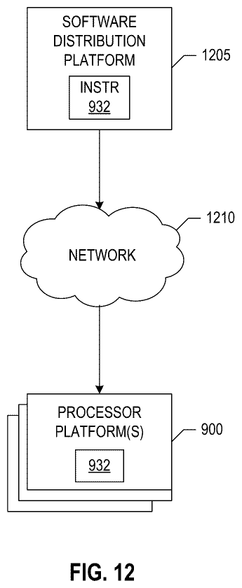

A block diagram illustrating an example software distribution platform 1205 to distribute software such as the example machine readable instructions 932 of FIG. 9 to other hardware devices (e.g., hardware devices owned and/or operated by third parties from the owner and/or operator of the software distribution platform) is illustrated in FIG. 12. The example software distribution platform 1205 may be implemented by any computer server, data facility, cloud service, etc., capable of storing and transmitting software to other computing devices. The third parties may be customers of the entity owning and/or operating the software distribution platform 1205. For example, the entity that owns and/or operates the software distribution platform 1205 may be a developer, a seller, and/or a licensor of software such as the example machine readable instructions 932 of FIG. 9. The third parties may be consumers, users, retailers, OEMs, etc., who purchase and/or license the software for use and/or re-sale and/or sub-licensing. In the illustrated example, the software distribution platform 1205 includes one or more servers and one or more storage devices. The storage devices store the machine readable instructions 932, which may correspond to the example machine readable instructions of FIGS. 4-6, as described above. The one or more servers of the example software distribution platform 1205 are in communication with an example network 1210, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 932 from the software distribution platform 1205. For example, the software, which may correspond to the example machine readable instructions of FIGS. 4-6, may be downloaded to the example programmable circuitry platform 900, which is to execute the machine readable instructions 932 to implement the control circuitry 112. In some examples, one or more servers of the software distribution platform 1205 periodically offer, transmit, and/or force updates to the software (e.g., the example machine readable instructions 932 of FIG. 9) to ensure improvements, patches, updates, etc., are distributed and applied to the software at the end user devices. Although referred to as software above, the distributed “software” could alternatively be firmware.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, “third”, “fourth”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a level, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., in circuit with, attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time+1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, chiplets that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that improve the performance of both compute-intense workloads and memory-intense workloads. Disclosed systems, apparatus, articles of manufacture, and methods improve the efficiency of using a computing device by implementing two paths to/from the main memory. The example control circuitry uses switch circuitry to route compute-intense workloads through the first path memory hierarchy, thereby improving performance through data locality. The example control circuitry uses the switch circuitry to route memory-intense workloads through the second path, which replaces the memory hierarchy with buffers and thereby improves performance by minimizing intermediate data and/or instruction transfers. Disclosed systems, apparatus, articles of manufacture, and methods are accordingly directed to one or more improvement(s) in the operation of a machine such as a computer or other electronic and/or mechanical device.

Example methods, apparatus, systems, and articles of manufacture to access main memory are disclosed herein. Further examples and combinations thereof include the following.

Example 1 includes an apparatus to access memory, the apparatus comprising main memory, a memory hierarchy in circuit with the main memory, buffer circuitry in circuit with the main memory, and control circuitry to cause delivery of data to programmable circuitry through the memory hierarchy or through the buffer circuitry.

Example 2 includes any preceding clause(s) of example 1, wherein the control circuitry is to couple the programmable circuitry to the main memory via the buffer circuitry, and after the coupling, instruct the main memory to write data to the buffer circuitry.

Example 3 includes any preceding clause(s) of examples 1-2, wherein after the control circuitry couples the programmable circuitry to the main memory via the buffer circuitry, the programmable circuitry is to read the data from the buffer circuitry in a First In First Out (FIFO) manner.

Example 4 includes any preceding clause(s) of examples 1-3, wherein a speed at which the main memory writes data to the buffer circuitry and a speed at which the programmable circuitry reads data from the buffer circuitry are different.

Example 5 includes any preceding clause(s) of examples 1-4, wherein the data is first data, the programmable circuitry is first programmable circuitry, and including second programmable circuitry, the control circuitry to couple the second programmable circuitry to the main memory via the memory hierarchy, and instruct the main memory to write second data to the memory hierarchy.

Example 6 includes any preceding clause(s) of examples 1-5, wherein the first programmable circuitry is to read the first data through the buffer circuitry and the second programmable circuitry is to read the second data through the memory hierarchy concurrently.

Example 7 includes any preceding clause(s) of examples 1-6, wherein the memory hierarchy includes a low level cache in circuit with the main memory, and an upper level cache in circuit with switch circuitry.

Example 8 includes any preceding clause(s) of examples 1-7, wherein the memory hierarchy includes a Network On a Chip (NOC) in circuit with both the low level cache and the upper level cache.

Example 9 includes any preceding clause(s) of examples 1-8, including switch circuitry, the control circuitry to selectively couple the programmable circuitry to the main memory by changing a state of the switch circuitry.

Example 10 includes any preceding clause(s) of examples 1-9, wherein a first terminal of the switch circuitry is a first input of a multiplexer, the first terminal in circuit with the memory hierarchy, a second terminal of the switch circuitry is a second input of the multiplexer, the second terminal in circuit with the buffer circuitry, a third terminal of the switch circuitry is an output of the multiplexer, the third terminal in circuit with the programmable circuitry, and the switch circuitry further includes a fourth terminal in circuit with the control circuitry, the fourth terminal to receive a signal from the control circuitry to cause the multiplexer to couple either the first input or the second input to the output.

Example 11 includes any preceding clause(s) of examples 1-10, wherein a first terminal of the switch circuitry is an input of a multiplexer, the first terminal in circuit with the main memory, a second terminal of the switch circuitry is a first output of the multiplexer, the second terminal in circuit with the buffer circuitry, a third terminal of the switch circuitry is a second output of the multiplexer, the third terminal in circuit with the memory hierarchy, and a fourth terminal of the switch circuitry is in circuit with the control circuitry, the fourth terminal to receive a signal from the control circuitry to cause the multiplexer to couple the input to either the first output or the second output.

Example 12 includes any preceding clause(s) of examples 1-11, wherein the buffer circuitry is input buffer circuitry, the switch circuitry is input switch circuitry, and including output buffer circuitry and output switch circuitry, the control circuitry to control the output switch circuitry to couple the programmable circuitry to the main memory via the output buffer circuitry, and instruct the programmable circuitry to write data to the output buffer circuitry.

Example 13 includes any preceding clause(s) of examples 1-12, wherein the control circuitry is to instruct the main memory to write first data to the memory hierarchy, based on a metric associated with the memory hierarchy decouple the programmable circuitry from the memory hierarchy and recouple the programmable circuitry to the buffer circuitry, and instruct the main memory to write second data to the buffer circuitry.

Example 14 includes any preceding clause(s) of examples 1-13, wherein the control circuitry is to determine the metric of the memory hierarchy by comparing a cache hit rate of a first level cache to a first threshold, or comparing a cache hit rate of a second level cache to a second threshold.

Example 15 includes a non-transitory machine readable storage medium comprising instructions to cause first programmable circuitry to at least cause delivery of data to second programmable circuitry through a memory hierarchy or through buffer circuitry.

Example 16 includes any preceding clause(s) of example 15, wherein the instructions cause the first programmable circuitry to couple the second programmable circuitry to the main memory via the buffer circuitry, and after the coupling, instruct the main memory to write data to the buffer circuitry.

Example 17 includes any preceding clause(s) of examples 15-16, wherein after the first programmable circuitry couples the second programmable circuitry to the main memory via the buffer circuitry, the instructions cause the second programmable circuitry to read the data from the buffer circuitry in a First In First Out (FIFO) manner.

Example 18 includes any preceding clause(s) of examples 15-17, wherein a speed at which the main memory writes data to the buffer circuitry and a speed at which the second programmable circuitry reads data from the buffer circuitry are different.

Example 19 includes any preceding clause(s) of examples 15-18, wherein the data is first data and the instructions cause the first programmable circuitry to couple third programmable circuitry to the main memory via the memory hierarchy, and instruct the main memory to write second data to the memory hierarchy.

Example 20 includes any preceding clause(s) of examples 15-19, wherein the instructions cause the second programmable circuitry to read the first data through the buffer circuitry and the third programmable circuitry to read the second data through the memory hierarchy concurrently.

Example 21 includes any preceding clause(s) of examples 15-20, wherein the memory hierarchy includes a low level cache in circuit with the main memory, and an upper level cache in circuit with switch circuitry.

Example 22 includes any preceding clause(s) of examples 15-21, wherein the memory hierarchy includes a Network On a Chip (NOC) in circuit with both the low level cache and the upper level cache.

Example 23 includes any preceding clause(s) of examples 15-22, wherein the instructions cause the first programmable circuitry to selectively couple the second programmable circuitry to the main memory by changing a state of switch circuitry.

Example 24 includes any preceding clause(s) of examples 15-23, wherein a first terminal of the switch circuitry is a first input of a multiplexer, the first terminal in circuit with the memory hierarchy, a second terminal of the switch circuitry is a second input of the multiplexer, the second terminal in circuit with the buffer circuitry, a third terminal of the switch circuitry is an output of the multiplexer, the third terminal in circuit with the programmable circuitry, and the switch circuitry further includes a fourth terminal in circuit with the first programmable circuitry, the fourth terminal to receive a signal from the first programmable circuitry to cause the multiplexer to couple either the first input or the second input to the output.

Example 25 includes any preceding clause(s) of examples 15-24, wherein a first terminal of the switch circuitry is an input of a multiplexer, the first terminal in circuit with the main memory, a second terminal of the switch circuitry is a first output of the multiplexer, the second terminal in circuit with the buffer circuitry, a third terminal of the switch circuitry is a second output of the multiplexer, the third terminal in circuit with the memory hierarchy, and a fourth terminal of the switch circuitry is in circuit with the first programmable circuitry, the fourth terminal to receive a signal from the first programmable circuitry to cause the multiplexer to couple the input to either the first output or the second output.

Example 26 includes any preceding clause(s) of examples 15-25, wherein the buffer circuitry is input buffer circuitry, the switch circuitry is input switch circuitry, and the instructions cause the first programmable circuitry to control output switch circuitry to couple the second programmable circuitry to the main memory via output buffer circuitry, and instruct the second programmable circuitry to write data to the output buffer circuitry.

Example 27 includes any preceding clause(s) of examples 15-26, wherein the instructions cause the first programmable circuitry to instruct the main memory to write first data to the memory hierarchy, based on a metric associated with the memory hierarchy decouple the programmable circuitry from the memory hierarchy and recouple the programmable circuitry to the buffer circuitry, and instruct the main memory to write second data to the buffer circuitry.

Example 28 includes any preceding clause(s) of examples 15-27, wherein the first programmable circuitry is to determine the metric of the memory hierarchy by comparing a cache hit rate of a first level cache to a first threshold, or comparing a cache hit rate of a second level cache to a second threshold.

Example 29 includes a method comprising causing delivery of data to programmable circuitry through a memory hierarchy or through buffer circuitry.

Example 30 includes any preceding clause(s) of example 29, including coupling the programmable circuitry to the main memory via the buffer circuitry, and after the coupling, instructing the main memory to write data to the buffer circuitry.

Example 31 includes any preceding clause(s) of examples 29-30, wherein after the coupling the programmable circuitry to the programmable circuitry via the buffer circuitry, the method includes reading, with the programmable circuitry, data from the buffer circuitry in a First In First Out (FIFO) manner.

Example 32 includes any preceding clause(s) of examples 29-31, wherein a speed at which the main memory writes data to the buffer circuitry and a speed at which the programmable circuitry reads data from the buffer circuitry are different.

Example 33 includes any preceding clause(s) of examples 29-32, wherein the data is first data, the programmable circuitry is first programmable circuitry, and the method includes coupling second programmable circuitry to the main memory via the memory hierarchy, and instructing the main memory to write second data to the memory hierarchy.

Example 34 includes any preceding clause(s) of examples 29-33, including reading, with the first programmable circuitry, first data through the buffer circuitry and reading, with the second programmable circuitry, second data through the memory hierarchy concurrently.

Example 35 includes any preceding clause(s) of examples 29-34, wherein the memory hierarchy includes a low level cache in circuit with the main memory, and an upper level cache in circuit with switch circuitry.

Example 36 includes any preceding clause(s) of examples 29-35, wherein the memory hierarchy includes a Network On a Chip (NOC) in circuit with both the low level cache and the upper level cache.

Example 37 includes any preceding clause(s) of examples 29-36, including selectively coupling the programmable circuitry to the main memory by changing a state of switch circuitry.

Example 38 includes any preceding clause(s) of examples 29-37, wherein a first terminal of the switch circuitry is a first input of a multiplexer, the first terminal in circuit with the memory hierarchy, a second terminal of the switch circuitry is a second input of the multiplexer, the second terminal in circuit with the buffer circuitry, a third terminal of the switch circuitry is an output of the multiplexer, the third terminal in circuit with the programmable circuitry, and the method includes providing a signal at a fourth terminal of multiplexer to cause the multiplexer to couple either the first input or the second input to the output.

Example 39 includes any preceding clause(s) of examples 29-38, wherein a first terminal of the switch circuitry is an input of a multiplexer, the first terminal in circuit with the main memory, a second terminal of the switch circuitry is a first output of the multiplexer, the second terminal in circuit with the buffer circuitry, a third terminal of the switch circuitry is a second output of the multiplexer, the third terminal in circuit with the memory hierarchy, and the method includes providing a signal to a fourth terminal of the multiplexer to cause the multiplexer to couple the input to either the first output or the second output.

Example 40 includes any preceding clause(s) of examples 29-39, wherein the buffer circuitry is input buffer circuitry, the switch circuitry is input switch circuitry, and the method includes controlling output switch circuitry to couple the programmable circuitry to the main memory via output buffer circuitry, and instructing the programmable circuitry to write data to the output buffer circuitry.

Example 41 includes any preceding clause(s) of examples 29-40, including instructing the main memory to write first data to the memory hierarchy, based on a metric associated with the memory hierarchy decoupling the programmable circuitry from the memory hierarchy and recouple the programmable circuitry to the buffer circuitry, and instructing the main memory to write second data to the buffer circuitry.

Example 42 includes any preceding clause(s) of examples 29-41, including determining the metric of the memory hierarchy by comparing a cache hit rate of a first level cache to a first threshold, or comparing a cache hit rate of a second level cache to a second threshold.

Example 43 includes an apparatus comprising means for storing data or instructions, first means for data or instruction transfer in circuit with the storage means, second means for data or instruction transfer in circuit with the storage means, means for implementing a workload, and controlling means to cause delivery of data to the implementing means through the first means for data or instruction transfer or through the second means for data or instruction transfer.

Example 44 includes any preceding clause(s) of example 43, wherein the controlling means is to couple the implementing means to the storage means via the second means for data or instruction transfer, and after the coupling, instruct the storage means to write data to the second means for data or instruction transfer.

Example 45 includes any preceding clause(s) of examples 43-44, wherein after the controlling means couples the implementing means to the storage means via the second means for data or instruction transfer, the implementing means is to read data from the second means for data or instruction transfer in a First In First Out (FIFO) manner.

Example 46 includes any preceding clause(s) of examples 43-45, wherein a) a speed at which the storage means writes data to the second means for data or instruction transfer and b) a speed at which the implementing means reads data from the second means for data or instruction transfer are different.

Example 47 includes any preceding clause(s) of examples 43-46, wherein the data is first data, the implementing means are first implementing means, and including second implementing means, the controlling means to couple the second implementing means to the storage means via the first means for data or instruction transfer, and instruct the storage means to write second data to the first means for data or instruction transfer.

Example 48 includes any preceding clause(s) of examples 43-47, wherein the first implementing means is to read first data through the second means for data or instruction transfer and the second implementing means is to read data through the first means for data or instruction transfer.

Example 49 includes any preceding clause(s) of examples 43-48, wherein the first means for data or instruction transfer includes a low level cache in circuit with the main memory, and an upper level cache in circuit with switch circuitry.

Example 50 includes any preceding clause(s) of examples 43-49, wherein the first means for data or instruction transfer includes a Network On a Chip (NOC) in circuit with both the low level cache and the upper level cache.

Example 51 includes any preceding clause(s) of examples 43-50, including switching means, the controlling means to selectively couple the implementing means to the storage means by changing a state of the switching means.

Example 52 includes any preceding clause(s) of examples 43-51, wherein a first terminal of the switching means is a first input of a multiplexer, the first terminal in circuit with the first means for data or instruction transfer, a second terminal of the switching means is a second input of the multiplexer, the second terminal in circuit with the second means for data or instruction transfer, a third terminal of the switching means is an output of the multiplexer, the third terminal in circuit with the implementing means, and the switching means further includes a fourth terminal in circuit with the controlling means, the fourth terminal to receive a signal from the controlling means to cause the multiplexer to couple either the first input or the second input to the output.

Example 53 includes any preceding clause(s) of examples 43-52, wherein a first terminal of the switching means is an input of a multiplexer, the first terminal in circuit with the storage means, a second terminal of the switching means is a first output of the multiplexer, the second terminal in circuit with the second means for data or instruction transfer, a third terminal of the switching means is a second output of the multiplexer, the third terminal in circuit with the first means for data or instruction transfer, and a fourth terminal of the switching means is in circuit with the controlling means, the fourth terminal to receive a signal from the controlling means to cause the multiplexer to couple the input to either the first output or the second output.

Example 54 includes any preceding clause(s) of examples 43-53, wherein the switching means is first switching means, including third means for data and instruction transfer and second switching means, the controlling means to control the second switching means to couple the implementing means to the storage means via the third means for data and instruction transfer, and instruct the implementing means to write data to the third means for data and instruction transfer.

Example 55 includes any preceding clause(s) of examples 43-54, wherein the controlling means is to instruct storage means to write first data to the first means for data or instruction transfer, based on a metric associated with the first means for data or instruction transfer decouple the implementing means from the first means for data or instruction transfer and recouple the implementing means to the second means for data or instruction transfer, and instruct the storage means to write second data to the second means for data or instruction transfer.

Example 56 includes any preceding clause(s) of examples 43-55, wherein the controlling means is to determine the metric of the first means for data or instruction transfer by comparing a cache hit rate of a first level cache to a first threshold, or comparing a cache hit rate of a second level cache to a second threshold.

Example 57 includes an apparatus comprising interface circuitry, machine readable instructions, and control circuitry to at least one of instantiate or execute the machine readable instructions to categorize a workload as memory-intense or compute-intense, and based on the categorization, selectively couple programmable circuitry to main memory via a memory hierarchy or via buffer circuitry.

Example 58 includes any preceding clause(s) of example 57, wherein the wherein the instructions cause the control circuitry to couple the programmable circuitry to the main memory via the memory hierarchy based on the categorization of the workload as compute-intense.

Example 59 includes any preceding clause(s) of examples 57-58, wherein the instructions cause the control circuitry to couple the programmable circuitry to the main memory via the buffer circuitry based on the categorization of the workload as memory-intense.

Example 60 includes any preceding clause(s) of examples 57-59, wherein the instructions cause the control circuitry to estimate an amount of data reusage in the workload, and categorize the workload as compute-intense if the amount of data reusage satisfies a threshold, and categorize the workload as memory-intense if the amount of data reusage fails to satisfy the threshold.

Example 61 includes any preceding clause(s) of examples 57-60, wherein the instructions cause the control circuitry to estimate the amount of data reusage by performing a static code analysis.

Example 62 includes any preceding clause(s) of examples 57-61, wherein the control circuitry is to determine the threshold based on one or more of a performance requirement of the workload, a data transfer rate of the memory hierarchy, a read speed of the programmable circuitry, a write speed of the programmable circuitry, a read speed of the main memory, or a write speed of the main memory.

Example 63 includes any preceding clause(s) of examples 57-62, wherein the instructions cause the control circuitry to categorize the workload as memory-intense if the workload corresponds to training a machine learning model, executing a machine learning model, graphics rendering, or high performance computing applications.

Example 64 includes any preceding clause(s) of examples 57-63, wherein the instruction cause the control circuitry to categorize the workload as a read-workload or a write-workload.

Example 65 includes a non-transitory machine readable storage medium comprising instructions to cause control circuitry to at least categorize a workload as memory-intense or compute-intense, and based on the categorization, selectively couple programmable circuitry to main memory via memory hierarchy or via buffer circuitry.

Example 66 includes any preceding clause(s) of example 65, wherein the instructions cause the control circuitry to couple the programmable circuitry to the main memory via the memory hierarchy based on the categorization of the workload as compute-intense.

Example 67 includes any preceding clause(s) of examples 65-66, wherein the instructions cause the control circuitry to couple the programmable circuitry to the main memory via the buffer circuitry based on the categorization of the workload as memory-intense.

Example 68 includes any preceding clause(s) of examples 65-67, wherein the instructions cause the control circuitry to estimate an amount of data reusage in the workload, and categorize the workload as compute-intense if the amount of data reusage satisfies a threshold, and categorize the workload as memory-intense if the amount of data reusage fails to satisfy the threshold.

Example 69 includes any preceding clause(s) of examples 65-68, wherein the instructions cause the control circuitry to estimate the amount of data reusage by performing a static code analysis.

Example 70 includes any preceding clause(s) of examples 65-69, wherein the control circuitry is to determine the threshold based on one or more of a performance requirement of the workload, a data transfer rate of the memory hierarchy, a read speed of the programmable circuitry, a write speed of the programmable circuitry, a read speed of the main memory, or a write speed of the main memory.

Example 71 includes any preceding clause(s) of examples 65-70, wherein the instructions cause the control circuitry to categorize the workload as memory-intense if the workload corresponds to training a machine learning model, executing a machine learning model, graphics rendering, or high performance computing applications.

Example 72 includes any preceding clause(s) of examples 65-71, wherein the instructions cause the control circuitry to categorize the workload as a read-workload or a write-workload.

Example 73 includes a method comprising categorizing a workload as memory-intense or compute-intense, and based on the categorization, selectively coupling programmable circuitry to main memory via memory hierarchy or via buffer circuitry.

Example 74 includes any preceding clause(s) of example 73, including coupling programmable circuitry to the main memory via the memory hierarchy based on categorizing the workload as compute-intense.

Example 75 includes any preceding clause(s) of examples 73-74, including coupling programmable circuitry to the main memory via the buffer circuitry based on the categorizing of the workload as memory-intense.

Example 76 includes any preceding clause(s) of examples 73-75, including estimating an amount of data reusage in the workload, and categorizing the workload as compute-intense if the amount of data reusage satisfies a threshold, and categorizing the workload as memory-intense if the amount of data reusage fails to satisfy the threshold.

Example 77 includes any preceding clause(s) of examples 73-76, including estimating the amount of data reusage by performing a static code analysis.

Example 78 includes any preceding clause(s) of examples 73-77, including determining the threshold based on one or more of a performance requirement of the workload, a data transfer rate of the memory hierarchy, a read speed of the programmable circuitry, a write speed of the programmable circuitry, a read speed of the main memory, or a write speed of the main memory.

Example 79 includes any preceding clause(s) of examples 73-78, including categorizing the workload as memory-intense if the workload corresponds to training a machine learning model, executing a machine learning model, graphics rendering, or high performance computing applications.

Example 80 includes any preceding clause(s) of examples 73-79, including categorizing the workload as a read-workload or a write-workload.

Example 81 includes an apparatus comprising means for storing data or instructions, first means for data or instruction transfer, second means for data or instruction transfer, means for implementing a workload, and controlling means to categorize a workload as memory-intense or compute-intense, and based on the categorization, selectively couple the implementing means to the storage means via the first means for data or instruction transfer or to the storage means via the second means for data or instruction transfer.

Example 82 includes any preceding clause(s) of example 81, wherein the controlling means is to couple the implementing means to the storage means via the first means for data or instruction transfer based on the categorization of the workload as compute-intense.

Example 83 includes any preceding clause(s) of examples 81-82, wherein the controlling means is to couple the implementing means to the storage means via the second means for data or instruction transfer based on the categorization of the workload as memory-intense.

Example 84 includes any preceding clause(s) of examples 81-83, wherein the controlling means is to estimate an amount of data reusage in the workload, and categorize the workload as compute-intense if the amount of data reusage satisfies a threshold, and categorize the workload as memory-intense if the amount of data reusage fails to satisfy the threshold.

Example 85 includes any preceding clause(s) of examples 81-84, wherein the controlling means is to estimate the amount of data reusage by performing a static code analysis.

Example 86 includes any preceding clause(s) of examples 81-85, wherein the controlling means is to determine the threshold based on one or more of a performance requirement of the workload, a data transfer rate of the first means for data or instruction transfer, a read speed of the implementing means, a write speed of the implementing means, a read speed of the storage means, or a write speed of the storage means.

Example 87 includes any preceding clause(s) of examples 81-86, wherein the controlling means is to categorize the workload as memory-intense if the workload corresponds to training a machine learning model, executing a machine learning model, graphics rendering, or high performance computing applications.

Example 88 includes any preceding clause(s) of examples 81-87, wherein the controlling means is to categorize the workload as a read-workload or a write-workload.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. An apparatus to access memory, the apparatus comprising:
main memory;
a memory hierarchy in circuit with the main memory;
buffer circuitry in circuit with the main memory; and
control circuitry to cause delivery of data to programmable circuitry through the memory hierarchy or through the buffer circuitry.

2. The apparatus of claim 1, wherein the control circuitry is to:
couple the programmable circuitry to the main memory via the buffer circuitry; and
after the coupling, instruct the main memory to write data to the buffer circuitry.

3. The apparatus of claim 2, wherein after the control circuitry couples the programmable circuitry to the main memory via the buffer circuitry, the programmable circuitry is to read the data from the buffer circuitry in a First In First Out (FIFO) manner.

4. The apparatus of claim 3, wherein a speed at which the main memory writes data to the buffer circuitry and a speed at which the programmable circuitry reads data from the buffer circuitry are different.

5. The apparatus of claim 2, wherein the data is first data, the programmable circuitry is first programmable circuitry, and including second programmable circuitry, the control circuitry to:
couple the second programmable circuitry to the main memory via the memory hierarchy; and
instruct the main memory to write second data to the memory hierarchy.

6. The apparatus of claim 5, wherein the first programmable circuitry is to read the first data through the buffer circuitry and the second programmable circuitry is to read the second data through the memory hierarchy concurrently.

7. The apparatus of claim 1, wherein the memory hierarchy includes:
a low level cache in circuit with the main memory; and
an upper level cache in circuit with switch circuitry.

8. The apparatus of claim 7, wherein the memory hierarchy includes a Network On a Chip (NOC) in circuit with both the low level cache and the upper level cache.

9. The apparatus of claim 1, including switch circuitry, the control circuitry to selectively couple the programmable circuitry to the main memory by changing a state of the switch circuitry.

10. The apparatus of claim 9, wherein:
a first terminal of the switch circuitry is a first input of a multiplexer, the first terminal in circuit with the memory hierarchy;
a second terminal of the switch circuitry is a second input of the multiplexer, the second terminal in circuit with the buffer circuitry;
a third terminal of the switch circuitry is an output of the multiplexer, the third terminal in circuit with the programmable circuitry; and
the switch circuitry further includes a fourth terminal in circuit with the control circuitry, the fourth terminal to receive a signal from the control circuitry to cause the multiplexer to couple either the first input or the second input to the output.

11. The apparatus of claim 9, wherein:
a first terminal of the switch circuitry is an input of a multiplexer, the first terminal in circuit with the main memory;
a second terminal of the switch circuitry is a first output of the multiplexer, the second terminal in circuit with the buffer circuitry;
a third terminal of the switch circuitry is a second output of the multiplexer, the third terminal in circuit with the memory hierarchy; and
a fourth terminal of the switch circuitry is in circuit with the control circuitry, the fourth terminal to receive a signal from the control circuitry to cause the multiplexer to couple the input to either the first output or the second output.)

12. The apparatus of claim 9, wherein:
the buffer circuitry is input buffer circuitry;
the switch circuitry is input switch circuitry;
the apparatus includes output buffer circuitry and output switch circuitry;
the control circuitry to:
control the output switch circuitry to couple the programmable circuitry to the main memory via the output buffer circuitry; and
instruct the programmable circuitry to write data to the output buffer circuitry.

13. The apparatus of claim 1, wherein the control circuitry is to:
instruct the main memory to write first data to the memory hierarchy;
based on a metric associated with the memory hierarchy:
decouple the programmable circuitry from the memory hierarchy and recouple the programmable circuitry to the buffer circuitry; and
instruct the main memory to write second data to the buffer circuitry.

14. The apparatus of claim 13, wherein the control circuitry is to determine the metric of the memory hierarchy by:
comparing a cache hit rate of a first level cache to a first threshold; or
comparing a cache hit rate of a second level cache to a second threshold.

15-42. (canceled)

43. An apparatus comprising:
means for storing data or instructions;
first means for data or instruction transfer in circuit with the storage means;
second means for data or instruction transfer in circuit with the storage means;
means for implementing a workload; and
controlling means to cause delivery of data to the implementing means through the first means for data or instruction transfer or through the second means for data or instruction transfer.

44. The apparatus of claim 43, wherein the controlling means is to:
couple the implementing means to the storage means via the second means for data or instruction transfer; and
after the coupling, instruct the storage means to write data to the second means for data or instruction transfer.

45.-46. (canceled)

47. The apparatus of claim 44, wherein the data is first data, the implementing means are first implementing means, and including second implementing means, the controlling means to:
couple the second implementing means to the storage means via the first means for data or instruction transfer; and
instruct the storage means to write second data to the first means for data or instruction transfer.)

48. The apparatus of claim 47, wherein the first implementing means is to read first data through the second means for data or instruction transfer and the second implementing means is to read data through the first means for data or instruction transfer concurrently.

49.-54. (canceled)

55. The apparatus of claim 43, wherein the controlling means is to:
instruct storage means to write first data to the first means for data or instruction transfer;
based on a metric associated with the first means for data or instruction transfer:
decouple the implementing means from the first means for data or instruction transfer and recouple the implementing means to the second means for data or instruction transfer; and
instruct the storage means to write second data to the second means for data or instruction transfer.

56. (canceled)

57. An apparatus comprising:
interface circuitry;
machine readable instructions; and
control circuitry to at least one of instantiate or execute the machine readable instructions to:
categorize a workload as memory-intense or compute-intense; and
based on the categorization, selectively couple programmable circuitry to main memory via a memory hierarchy or via buffer circuitry.

58. The apparatus of claim 57, wherein the wherein the instructions cause the control circuitry to couple the programmable circuitry to the main memory via the memory hierarchy based on the categorization of the workload as compute-intense.

59. The apparatus of claim 57, wherein the instructions cause the control circuitry to couple the programmable circuitry to the main memory via the buffer circuitry based on the categorization of the workload as memory-intense.

60. The apparatus of claim 57, wherein the instructions cause the control circuitry to:
estimate an amount of data reusage in the workload; and
categorize the workload as compute-intense if the amount of data reusage satisfies a threshold; and
categorize the workload as memory-intense if the amount of data reusage fails to satisfy the threshold.

61. The apparatus of claim 60, wherein the instructions cause the control circuitry to estimate the amount of data reusage by performing a static code analysis.

62. The apparatus of claim 60, wherein the control circuitry is to determine the threshold based on one or more of: a performance requirement of the workload, a data transfer rate of the memory hierarchy, a read speed of the programmable circuitry, a write speed of the programmable circuitry, a read speed of the main memory, or a write speed of the main memory.

63. The apparatus of claim 57, wherein the instructions cause the control circuitry to categorize the workload as memory-intense if the workload corresponds to training a machine learning model, executing a machine learning model, graphics rendering, or high performance computing applications.)

64. The apparatus of claim 57, wherein the instruction instructions cause the control circuitry to categorize the workload as a read-workload or a write-workload.

65.-80. (canceled)

81. An apparatus comprising:
means for storing data or instructions;
first means for data or instruction transfer;
second means for data or instruction transfer;
means for implementing a workload; and
controlling means to:
categorize a workload as memory-intense or compute-intense; and
based on the categorization, selectively couple the implementing means to the storage means via the first means for data or instruction transfer or to the storage means via the second means for data or instruction transfer.

82. The apparatus of claim 81, wherein the controlling means is to couple the implementing means to the storage means via the first means for data or instruction transfer based on the categorization of the workload as compute-intense.

83. The apparatus of claim 81, wherein the controlling means is to couple the implementing means to the storage means via the second means for data or instruction transfer based on the categorization of the workload as memory-intense.

84.-88. (canceled)
